(19) United States
(12) Patent Application Publication
(10) Pub. No.: US 2026/0190754 A1
(43) Pub. Date: Jul. 2, 2026

(54) DISPLAY DEVICE AND ELECTRONIC DEVICE INCLUDING THE SAME

(71) Applicant: Samsung Display Co., LTD., Yongin-si (KR)

(72) Inventors: Sun Ho KIM, Yongin-si (KR); Yoo Min KO, Yongin-si (KR); Ju Chan PARK, Yongin-si (KR); Chung Sock CHOI, Yongin-si (KR)

(21) Appl. No.: 19/268,160

(22) Filed: Jul. 14, 2025

(30) Foreign Application Priority Data
Jan. 2, 2025 (KR) 10-2025-0000481

(51) Int. Cl. H10K 59/80; H10K 59/131

(52) U.S. Cl. CPC H10K 59/80516; H10K 59/131

(57) ABSTRACT

A display device includes a pixel circuit layer including a via-layer and an auxiliary electrode; and a pixel electrode disposed on the via-layer and spaced apart from each other. The via-layer includes a raised portion comprising a first flat portion and a second flat portion spaced apart from the first flat portion, and a recessed portion defining a groove recessed along a periphery of the raised portion. The auxiliary electrode includes a first auxiliary electrode portion defining a first opening exposing a portion of the first flat portion, and a second auxiliary electrode portion defining a second opening exposing a portion of the second flat portion. The pixel electrode includes a first pixel electrode disposed on the first flat portion exposed by the first opening, and a second pixel electrode disposed on the second flat portion exposed by the second opening.

This application claims priority to Korean patent application number 10-2025-0000481, filed on Jan. 2, 2025, and all the benefits accruing therefrom under 35 U.S.C. § 119, the content of which in its entirety is herein incorporated by reference.

### BACKGROUND

### Field of Invention

The present disclosure relates to a display device and an electronic device including the same.

### Description of Related Art

A display device (and an electronic device including the same) may display an image. The display device may display an image by combining light emitted from pixels, and each of the pixels may include a plurality of sub-pixels.

In case that lateral leakage current occurs between sub-pixels adjacent to each other, a problem in which color and luminance of light emitted from the sub-pixels cannot be controlled may occur, and thus display quality of the display device may be deteriorated.

### SUMMARY

The present disclosure provides a display device with improved display quality.

The present disclosure provides an electronic device including the display device.

A display device according to embodiments of the present disclosure includes: a pixel circuit layer including a via-layer; and an auxiliary electrode and a pixel electrode disposed on the via-layer and spaced apart from each other. The via-layer includes: a raised portion including a first flat portion and a second flat portion spaced apart from the first flat portion; and a recessed portion defining a groove recessed along a periphery of the raised portion. The auxiliary electrode includes: a first auxiliary electrode portion defining a first opening exposing a portion of the first flat portion; and a second auxiliary electrode portion defining a second opening exposing a portion of the second flat portion. The pixel electrode includes: a first pixel electrode disposed on the first flat portion exposed by the first opening; and a second pixel electrode disposed on the second flat portion exposed by the second opening. A first undercut is defined by the first auxiliary electrode portion and a portion of the recessed portion adjacent to the first flat portion. A second undercut is defined by the second auxiliary electrode portion and a portion of the recessed portion adjacent to the second flat portion.

In an embodiment, the auxiliary electrode may include a polycrystalline transparent conductive oxide.

In an embodiment, the auxiliary electrode may include a polycrystalline indium tin oxide (p-ITO)

In an embodiment, the auxiliary electrode may be a single-layer structure.

In an embodiment, the pixel electrode may include a metal.

In an embodiment, the pixel electrode may be a multi-layer structure including: a first pixel electrode layer including a transparent conductive oxide; a second pixel electrode layer including a metal; and a third pixel electrode layer including a transparent conductive oxide.

In an embodiment, the display device may further include: a light emitting structure disposed on the via-layer, the auxiliary electrode, and the pixel electrode; and a common electrode disposed on the light emitting structure.

In an embodiment, each of the light emitting structure and the common electrode may be disconnected by the first undercut and the second undercut.

In an embodiment, the common electrode may electrically contact the auxiliary electrode.

In an embodiment, the common electrode may electrically contact each of a side surface of the first auxiliary electrode portion adjacent to the first undercut and a side surface of the second auxiliary electrode portion adjacent to the second undercut.

In an embodiment, the light emitting structure may be disposed between the common electrode and each of an upper surface of the first auxiliary electrode portion adjacent to the side surface of the first auxiliary electrode portion and an upper surface of the second auxiliary electrode portion adjacent to the side surface of the second auxiliary electrode portion.

In an embodiment, the first auxiliary electrode portion may overlap a boundary between the first flat portion and the recessed portion in a plan view, and the second auxiliary electrode portion may overlap a boundary between the second flat portion and the recessed portion in the plan view.

In an embodiment, the raised portion may further include a first connection portion between the first flat portion and the second flat portion, and the auxiliary electrode may further include a first connection electrode portion disposed on the first connection portion and electrically connecting the first auxiliary electrode portion and the second auxiliary electrode portion to each other.

In an embodiment, the auxiliary electrode may further include an auxiliary voltage receiving portion extending from the first auxiliary electrode portion toward the first pixel electrode, and the auxiliary voltage receiving portion may be electrically connected to an auxiliary voltage line included in the pixel circuit layer through a through-hole defined in the first flat portion.

In an embodiment, the display device may further include: a first pixel defining layer disposed on the first flat portion in the first opening and exposing at least a portion of the first pixel electrode; and a second pixel defining layer disposed on the second flat portion in the second opening and exposing at least a portion of the second pixel electrode.

In an embodiment, the raised portion may further include a third flat portion spaced apart from the first and the second flat portions, the auxiliary electrode may further include a third auxiliary electrode portion defining a third opening exposing a portion of the third flat portion, the pixel electrode may further include a third pixel electrode disposed on the third flat portion exposed by the third opening, and a third undercut may be defined by the third auxiliary electrode and a portion of the recessed portion adjacent to the third flat portion.

In an embodiment, the common electrode may electrically contact a side surface of the third auxiliary electrode portion adjacent to the third undercut.

In an embodiment, the third auxiliary electrode portion may overlap a boundary between the third flat portion and the recessed portion in a plan view.

In an embodiment, the raised portion may further include a second connection portion between the first flat portion and the third flat portion, and the auxiliary electrode may further include a second connection electrode portion disposed on the second connection portion and electrically connecting the first auxiliary electrode portion and the third auxiliary electrode portion to each other.

An electronic device according to embodiments of the present disclosure includes: a display device, which displays an image; and a processor, which provides an image data signal to the display device. The display device includes: a pixel circuit layer including a via-layer; and an auxiliary electrode and a pixel electrode disposed on the via-layer and spaced apart from each other. The via-layer includes: a raised portion including a first flat portion and a second flat portion spaced apart from the first flat portion; and a recessed portion defining a groove recessed along a periphery of the raised portion. The auxiliary electrode includes: a first auxiliary electrode portion defining a first opening exposing a portion of the first flat portion; and a second auxiliary electrode portion defining a second opening exposing a portion of the second flat portion. The pixel electrode includes: a first pixel electrode disposed on the first flat portion exposed by the first opening; and a second pixel electrode disposed on the second flat portion exposed by the second opening. A first undercut is defined by the first auxiliary electrode portion and a portion of the recessed portion adjacent to the first flat portion. A second undercut is defined by the second auxiliary electrode portion and a portion of the recessed portion adjacent to the second flat portion.

In a display device according to the present disclosure, the first undercut and the second undercut may serve to prevent lateral leakage current from generating between sub-pixels adjacent to each other. As the generation of the lateral leakage current is prevented in this way, the display quality of the display device may be effectively improved.

An electronic device according to the present disclosure may include the above-mentioned display device, and thus may provide an image with improved display quality.

### BRIEF DESCRIPTION OF THE DRAWINGS

FIG. 1 is a block diagram illustrating a display device according to an embodiment of the present disclosure.

FIG. 2 is a block diagram illustrating an embodiment of any one sub-pixel among sub-pixels included in the display device of FIG. 1.

FIG. 3 is a plan view illustrating an embodiment of a display panel included in the display device of FIG. 1.

FIG. 4 is a cross-sectional view illustrating an embodiment of the display panel of FIG. 3.

FIG. 5 is a cross-sectional view illustrating another embodiment of the display panel of FIG. 3.

FIGS. 6 to 16 are diagrams illustrating any one pixel among pixels included in the display panel of FIG. 3.

FIG. 17 is a cross-sectional view illustrating an embodiment of a pixel electrode.

FIG. 18 is a cross-sectional view illustrating an embodiment of a light emitting structure.

FIG. 19 is a cross-sectional view illustrating another embodiment of a light emitting structure.

FIGS. 20 to 37 are diagrams illustrating a method of manufacturing the pixel of FIG. 10.

FIG. 38 is a block diagram of an electronic device according to an embodiment.

FIG. 39 shows schematic views of various embodiments of an electronic device.

### DETAILED DESCRIPTION

Hereinafter, an embodiment of the present invention will be described in detail with reference to the attached drawings. In the following description, only parts required for understanding of operations in accordance with the present disclosure will be described, and explanation of the other parts will be omitted not to make the gist of the present disclosure unclear. Accordingly, the present disclosure is not limited to the embodiments set forth herein but may be embodied in other types. Rather, these embodiments are provided so that the present disclosure will be thorough and complete, and will fully convey the technical spirit of the disclosure to those skilled in the art.

It will be understood that when an element is referred to as being “coupled” or “connected” to another element, it can be directly coupled or connected to the other element or indirectly coupled or connected to the other element with intervening elements therebetween. The terminology used herein is for the purpose of describing particular embodiments only and is not intended to be limiting. In the specification, when an element is referred to as “comprising” or “including” a component, it does not preclude another component but may further include other components unless the context clearly indicates otherwise. “at least one of X, Y, and Z” and “at least one selected from the array consisting of X, Y, and Z” may be construed as X only, Y only, Z only, or any combination of two or more of X, Y, and Z (for instance, XYZ, XYY, YZ, and ZZ). The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” can include any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element or feature's relationship to another element(s) or feature(s), as illustrated in the drawings. Spatially relative terms are intended to encompass different orientations of an apparatus in use, operation, and/or manufacture in addition to the orientation depicted in the drawings. For example, if the device in the drawings is turned upside down, elements described as “below” or “beneath” other elements or features would then be oriented “above” the other elements or features. Thus, the term “below” can encompass both an orientation of above and below. Furthermore, the device may be otherwise oriented (e.g., rotated 90 degrees or at other orientations), and, as such, the spatially relative descriptors used herein interpreted accordingly.

Various embodiments will be described with reference to diagrams illustrating idealized embodiments. As such, variations from the shapes of the illustrations as a result, for example, of manufacturing techniques and/or tolerances, are to be expected. Therefore, embodiments disclosed herein should not be construed as limited to the particular illustrated shapes of regions, but are to include deviations in shapes that result from, for instance, manufacturing. As such, the shapes illustrated in the drawings may not illustrate the actual shapes of regions of a device, and, as such, are not intended to be limiting.

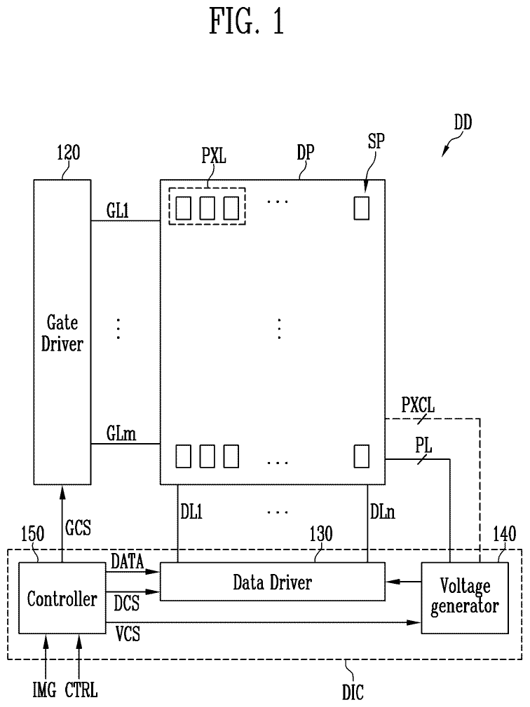

FIG. 1 is a block diagram illustrating a display device according to an embodiment of the present disclosure.

Referring to FIG. 1, a display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, the sub-pixels SP may generate light of red, green, blue, cyan, magenta, or yellow.

Two or more sub-pixels among the sub-pixel SP may constitute one pixel PXL. For example, the pixel PXL may include three sub-pixels SP as shown in FIG. 1. The pixel PXL may emit light of various colors and various luminances according to combination of light emitted from the sub-pixels SP included in the pixel PXL.

The gate driver 120 may be connected to sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating start of each frame, and a horizontal synchronization signal.

The gate driver 120 may be disposed at a side of the display panel DP. However, embodiments are not limited thereto. For example, the gate driver 120 may be divided into two or more physically and/or logically separated drivers, and the drivers may be disposed at one side of the display panel DP and at other side of the display panel DP opposite to the one side. As such, the gate driver 120 may be disposed around the display panel DP in various forms according to embodiments.

The data driver 130 may be connected to the sub-pixels SP arranged in a column direction through the first to n-th data lines DL1 to DLn. The data driver 130 may receive a image data DATA and a data control signal DCS from the controller 150. The data driver 130 may operate in response to the data control signal DCS. In embodiments, the data control signal DCS may include a source start signal, a source shift clock, and/or a source output enable signal.

The data driver 130 may receive voltages from the voltage generator 140. The data driver 130 may use received voltages to apply data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLn. Accordingly, the sub-pixels SP may generate light corresponding to the data signals, and the display panel DP may display an image.

In embodiments, the gate driver 120 and the data driver 130 may include CMOS(complementary metal-oxide semiconductor) circuit elements.

The voltage generator 140 may operate in response to a voltage control signal VCS from the controller 150. The voltage generator 140 may generate voltages and provide the generated voltages to components of display device DD such as the gate driver 120, the data driver 130, and the controller 150. The voltage generator 140 may generate voltages by receiving an input voltage from outside of the display device DD and regulating the received voltage.

The voltage generator 140 may generate a first power voltage and a second power voltage. The generated first and second voltages may be provided to the sub-pixels through power lines PL. In another embodiments, at least one of the first and second power voltages may be provided from outside of the display device DD.

In addition, the voltage generator 140 may provide various voltages and/or various signals. For example, the voltage generator 140 may provide one or more initialization voltages applied to the sub-pixels SP. For example, in a sensing operation for sensing electrical characteristics of transistors and/or light emitting elements of the sub-pixels SP, a predetermined reference voltage may be applied to the first to n-th data lines DL1 to DLn, and the voltage generator 140 may generate and transmit the reference voltage to the data driver 130. For example, in a display operation for displaying an image on the display panel DP, pixel control signals may be commonly applied to the sub-pixels SP, and the voltage generator 140 may generate the pixel control signals. In embodiments, voltage generator 140 may provide pixel control signals to the sub-pixels SP through pixel control lines PXCL. Although the pixel control lines PXCL are shown in FIG. 1 as being connected between the voltage generator 140 and the display panel DP, embodiments are not limited thereto. For example, the pixel control lines PXCL may be connected between the gate driver 120 and the display panel DP. In this case, the pixel control signals may be transmitted from the voltage generator 140 to the pixel control lines PXCL through the gate driver 120.

The controller 150 may control various operations of the display device DD. The controller 150 may receive an input image data IMG and a corresponding control signal CTRL from outside. The controller 150 may provide the gate control signal GCS, the data control signal DCS, and a voltage control signal VCS in response to the control signal CTRL.

The controller 150 may output the image data DATA by converting the input image data IMG to be suitable for the display device DD or the display panel DP. In embodiments, the controller 150 may output the image data DATA by aligning the input image data IMG to fit the sub-pixels SP in rows.

Two or more components among the data driver 130, the voltage generator 140, and the controller 150 may be integrated in one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally distinct components within one driver integrated circuit DIC. In another embodiments, at least one of the data driver 130, the voltage generator 140, and the controller 150 may be provided as a component separate from the driver integrated circuit DIC.

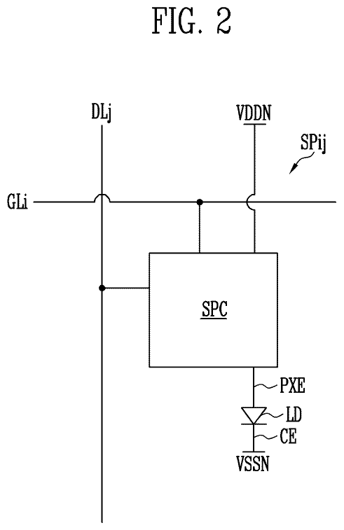

FIG. 2 is a block diagram illustrating an embodiment of any one sub-pixel among sub-pixels included in the display device of FIG. 1. In FIG. 2, a sub-pixel SPij arranged in a i-th row (i is an integer greater than or equal to 1 and less than or equal to m) and a j-th column (j is an integer greater than or equal to 1 and less than or equal to n) among the sub-pixels SP in FIG. 1 is exemplarily shown.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL of FIG. 1 to receive a first power voltage. The second power voltage node VSSN may be connected to another one of the power lines PL of FIG. 1 to receive a second power voltage. In an embodiment, the first power voltage may have a higher voltage level than the second power voltage.

The light emitting element LD may be connected between a pixel electrode PXE and a common electrode CE. The pixel electrode PXE may be connected to the first power voltage node VDDN through the sub-pixel circuit SPC. For example, the pixel electrode PXE may be connected to the first power voltage node VDDN through one or more transistors included in the sub-pixel circuit SPC. The common electrode CE may be connected to the second power voltage node VSSN. The light emitting element LD may emit light depending on a current flowing from a pixel electrode PXE to a common electrode CE.

The sub-pixel circuit SPC may be connected to a i-th gate line GLi among the first to m-th gate lines GL1 to GLm of FIG. 1 and a j-th data line DLj among the first to n-th data lines DL1 to DLn of FIG. 1. In response to a gate signal received through the i-th gate line GLi, the sub-pixel circuit SPC may control the light emitting element LD to emit light in accordance with a data signal received through the j-th data line DLj. In embodiments, the sub-pixel circuit SPC may be further connected to the pixel control lines PXCL of FIG. 1. In this case, the sub-pixel circuit SPC may control the light emitting element LD in further response to pixel control signals received through the pixel control lines PXCL.

To perform the operations described above, the sub-pixel circuit SPC may include circuit elements (e.g., transistors and one or more capacitors).

The transistors of the sub-pixel circuit SPC may include p-type transistors and/or n-type transistors. In embodiments, the transistors of the sub-pixel circuit SPC may include MOSFET(metal oxide silicon filed effect transistor). In embodiments, the transistors of the sub-pixel circuit SPC may include amorphous silicon semiconductor, monocrystalline silicon semiconductor, polycrystalline silicon semiconductor, and/or oxide semiconductor.

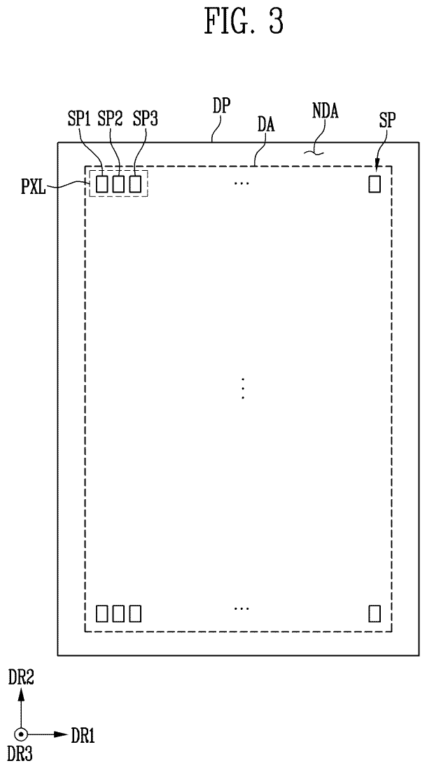

FIG. 3 is a plan view illustrating an embodiment of a display panel included in the display device of FIG. 1. As used herein, the “plan view” is a view in a thickness direction (i.e., third direction DR3) of the display device.

Referring to FIG. 3, the display panel DP may include a display area DA and a non-display area NDA. The display panel DP may display an image through the display area DA. The non-display area NDA may be disposed around the display area DA.

The display panel DP may include the sub-pixels SP disposed in the display area DA. The sub-pixels SP may be arranged along a first direction DR1 and a second direction DR2 crossing the first direction DR1. In an embodiment, the sub-pixels SP may be arranged in a matrix-form along the first direction DR1 and the second direction DR2. In another embodiment, the sub-pixels SP may be arranged in a zigzag-from along the first direction DR1 and the second direction DR2. The arrangement of the sub-pixels SP may vary according to embodiments. The first direction DR1 may be the row direction, and the second direction DR2 may be the column direction.

Two or more sub-pixels SP among the sub-pixels SP may constitute one pixel PXL. Although the pixel PXL is shown in FIG. 3 as including three sub-pixels SP1, SP2, and SP3, embodiments are not limited thereto. For example, the pixel PXL may include two sub-pixels. Hereinafter, for convenience of description, it is assumed that the pixel PXL includes first to third sub-pixels SP1, SP2, and SP3.

Each of the first to third sub-pixels SP1, SP2, and SP3 may generate light such as red, green, blue, cyan, magenta, or yellow. Hereinafter, for clear and concise description, it is assumed that the first sub-pixel SP1 is configured to generate blue light, the second sub-pixel SP2 is configured to generate red light, and the third sub-pixel SP3 is configured to generate green light.

Each of the first to third sub-pixels SP1, SP2, and SP3 may include at least one light emitting element configured to generate light. In an embodiment, light emitting elements of the first to third sub-pixels SP1, SP2, and SP3 may generate light of same color. For example, the light emitting elements of the first to third sub-pixels SP1, SP2, and SP3 may generate white light. In another embodiment, light emitting elements of the first to third sub-pixels SP1, SP2, and SP3 may generate light of different colors. For example, the light emitting elements of the first to third sub-pixels SP1, SP2, and SP3 may generate light of red color, green color, and blue color, respectively.

As the display panel DP, a self-luminous display panel such as a LED display panel using a micro-scale or nano-scale light emitting diode as a light emitting element, and organic light emitting display panel (OLED panel) using an organic light emitting diode, or the like may be used.

In the non-display area NDA, a component for controlling the sub-pixels may be disposed. Lines connected to the sub-pixels SP, for example, the first to m-th gate lines GL1 to GLm, the first to n-th data lines DL1 to DLn, the power lines PL, and the pixel control lines PXCL of FIG. 1 may be disposed in the non-display area.

At least one of the gate driver 120, the data driver 130, the voltage generator 140, and the controller 150 of FIG. 1 may be disposed in the non-display area NDA of the display panel DP. In an embodiment, the gate driver 120 may be disposed in the non-display area NDA. In this case, the data driver 130, the voltage generator 140, and the controller 150 may be implemented as the driver integrated circuit DIC of FIG. 1 separated from the display panel DP, and the driver integrated circuit DIC may be connected to lines disposed in the non-display area NDA. In another embodiment, the gate driver 120 may be implemented as one integrated circuit separated from the display panel DP together with the data driver 130, the voltage generator 140, and the controller 150.

In embodiments, the display area DA may have various shapes. The display area DA may have a closed-loop shape including straight and/or curved sides. For example, the display area DA may have shapes such as a polygon, a circle, a semicircle, an ellipse, etc.

In embodiments, the display panel DP may have flat display surface. In another embodiments, the display panel may have at least partially rounded display surface. In embodiments, the display panel DP may be bendable, foldable, or rollable, In such embodiments, the display panel DP may include materials having flexible characteristic.

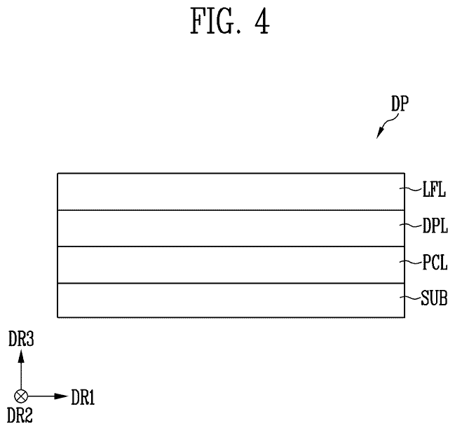

FIG. 4 is a cross-sectional view illustrating an embodiment of the display panel of FIG. 3.

Referring to FIG. 4, the display panel DP may include a substrate SUB, and a pixel circuit layer PCL, a display element layer DPL, and a light functional layer LFL sequentially stacked along a third direction DR3 crossing the first and second directions DR1 and DR2 on the substrate SUB.

The substrate SUB may be made of an insulating material such as glass, resin. For example, the substrate SUB may include a glass substrate. For another example, the substrate SUB may include PI(polyimide) substrate. For still another example, the substrate SUB may include silicon wafer substrate formed using a semiconductor process.

In embodiments, the substrate SUB may be made of a flexible material that can be bent or folded, and may have a single-layer structure or a multi-layer structure. For example, the substrate SUB may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers and semiconductor patterns and conductive patterns disposed between the insulating layers. The conductive patterns of the pixel circuit layer PCL may function as circuit elements, lines, or the like.

The circuit elements of the pixel circuit layer PCL may include the sub-pixel circuit SPC (refer to FIG. 2) of each of the sub-pixels SP of FIG. 3. In other words, the circuit elements of the pixel circuit layer PCL may be provided with transistors and one or more capacitors of the sub-pixel circuit SPC.

Lines of the pixel circuit layer PCL may include lines connected to the sub-pixels SP. The lines of the pixel circuit layer PCL may include various signals lines and/or voltage lines for driving the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include a light conversion patterns including light conversion particles and/or scattering particles. For example, the light conversion particles may include quantum dots. The quantum dots may convert wavelength (or color) of light emitted from the display element layer DPL. The light functional layer LFL may further include light scattering patterns including scattering particles. In embodiments, light conversion patterns and light scattering patterns may be omitted.

The light functional layer LFL may further include a color filter layer including color filters. The color filter may selectively transmit light of a particular wavelength (or color). In embodiments, the color filter layer may be omitted.

A window for protecting an exposed surface (or an upper surface) of the display panel DP may be disposed on the light functional layer LFL. The window may protect the display panel DP from external impact. The window may be coupled to the light functional layer LFL through an optically transparent adhesive (or bonding) member. The window may have a multi-layer structure including a glass substrate, a plastic film, and/or a plastic substrate. Such multi-layer structure may be formed through a continuous process or an adhesive process using an adhesive layer. All or a part of the window may have flexibility.

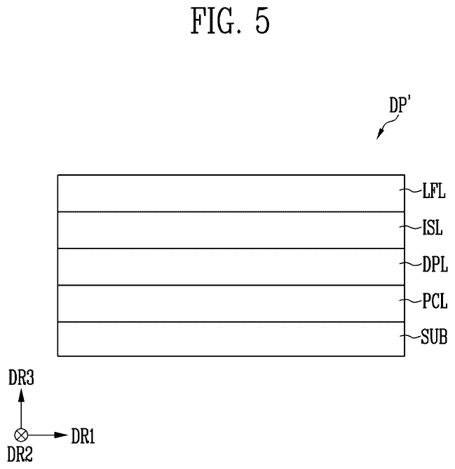

FIG. 5 is a cross-sectional view illustrating another embodiment of the display panel of FIG. 3.

Referring to FIG. 5, a display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL may be described in the same manner as the substrate SUB, the pixel circuit layer PCL, the display element layer DPL, and the light functional layer LFL with reference to FIG. 4, respectively, and redundant descriptions will be omitted.

The input sensing layer ISL may sense a user's input to an upper surface (or a display surface) of the display panel DP′. The input sensing layer ISL may include components suitable for sensing external objects such as a user's hand, a pen, etc. For example, the input sensing layer ISL may include touch electrodes.

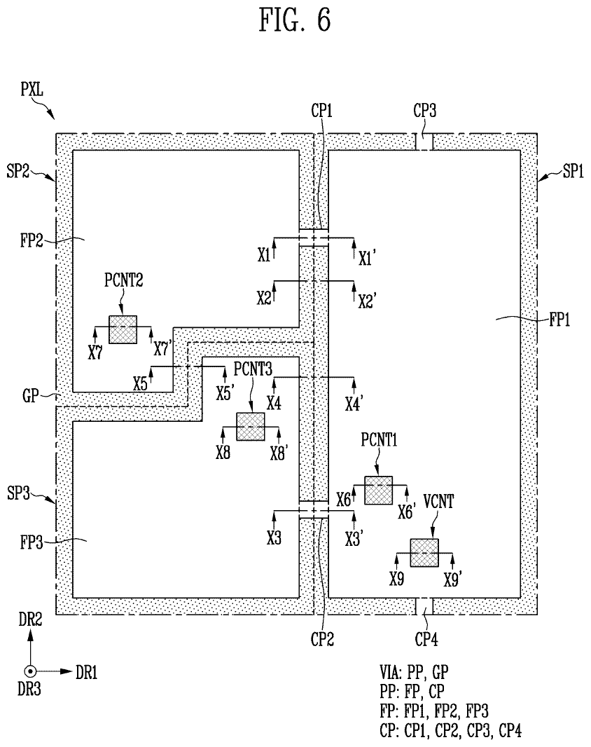

FIGS. 6 to 16 are diagrams illustrating any one pixel among pixels included in the display panel of FIG. 3.

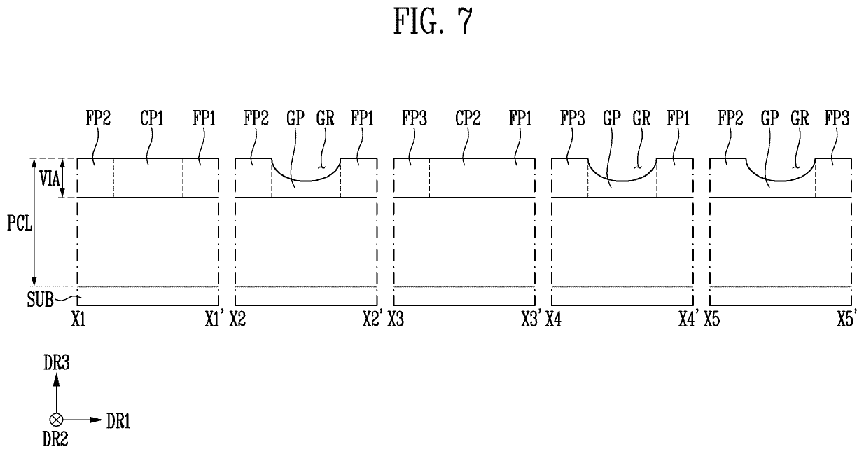

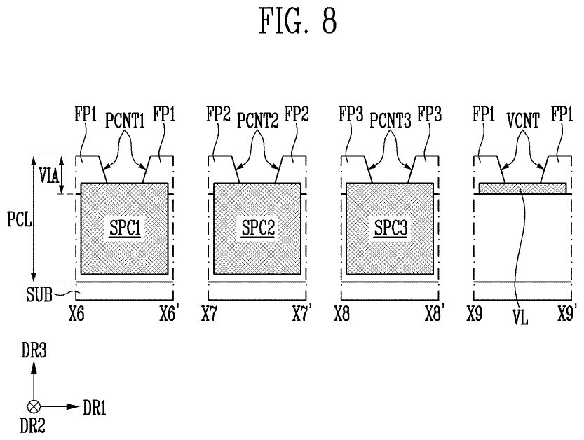

FIG. 6 is a plan view illustrating a pixel circuit layer PCL constituting a pixel PXL, FIG. 7 is a cross-sectional view taken along line X1-X1′, line X2-X2′, line X3-X3′, line X4-X4′, and line X5-X5′ of FIG. 6, and FIG. 8 is a cross-sectional view taken along line X6-X6′, line X7-X7′, line X8-X8′, and line X9-X9′ of FIG. 6.

Referring to FIG. 6 to FIG. 8, a pixel PXL may include a substrate SUB and a pixel circuit layer PCL, and the pixel circuit layer PCL may include a via-layer VIA. In an embodiment, the via-layer VIA may be an uppermost layer of the pixel circuit layer PCL, and include organic insulating material and/or inorganic insulating material.

In an embodiment, a groove GR may be defined in some areas of the via-layer VIA. A portion where the groove GR is defined in the via-layer VIA may be referred to as a recessed portion GP, and a portion where the groove GR is not defined in the via-layer VIA may be referred to as a raised portion PP.

That is, the via-layer VIA may include the raised portion PP and the recessed portion GP. The recessed portion GP may be a portion defining the groove GR that is recessed along a periphery of the raised portion PP. The raised portion PP may be a portion other than the recessed portion GP, and may be a portion where the groove GR is not defined. A level of an upper surface of the raised portion PP may be higher than a level of an upper portion of the recessed portion GP.

In an embodiment, the raised portion PP may include a flat portion FP and a connection portion CP.

The flat portion FP may include a first flat portion FP1, a second flat portion FP2, and a third flat portion FP3. The first flat portion FP1 may be disposed in an area where a first sub-pixel SP1 is provided. The second flat portion FP2 may be spaced apart from the first flat portion FP1, and may be disposed in an area where a second sub-pixel SP2 is provided. The third flat portion FP3 may be spaced apart from the first and the second flat portions FP1 and FP2, and may be disposed in an area where a third sub-pixel SP3 is provided.

The connection portion CP may include a first connection portion CP1, a second connection portion CP2, a third connection portion CP3, and a fourth connection portion CP4.

The first connection portion CP1 may be disposed between the first flat portion FP1 and the second flat portion FP2. In an embodiment, one end of the first connection portion CP1 may contact the first flat portion FP1, and the other end of the first connection portion CP2 may contact the second flat portion FP2. In an embodiment, a level of an upper surface of the first connection portion CP1 may be substantially the same height as each of a level of an upper surface of the first flat portion FP1 and a level of an upper surface of the second flat portion FP2.

The second connection portion CP2 may be disposed between the first flat portion FP1 and third flat portion FP3. In an embodiment, one end of the second connection portion CP2 may contact the first flat portion FP1, and the other end of the second connection portion CP2 may contact the third flat portion FP3. In an embodiment, a level of an upper surface of the second connection portion CP2 may be substantially the same height as each of the level of the upper surface of the first flat portion FP1 and a level of an upper surface of the third flat portion FP3.

The third connection portion CP3 and the fourth connection portion CP4 may be disposed on one side of the first flat portion FP1 and the other side of the first flat portion FP1 opposite thereto, respectively. In an embodiment, one end of the third connection portion CP3 may contact the one side of the first flat portion FP1, and one end of the fourth connection portion CP4 may contact the other side of the first flat portion FP1. In an embodiment, each of a level of an upper surface of the third connection portion CP3 and a level of an upper surface of the fourth connection portion may be substantially the same height as the level of the upper surface of the first flat portion FP1.

In an embodiment, in an area other than an area where the connection portion CP is disposed, the groove GR may be defined between the first flat portion FP1, the second flat portion FP2, and the third flat portion FP3. In an embodiment, in the area other than the area where the connection portion CP is disposed, the groove GR may surround the first flat portion FP1, the second flat portion FP2, and the third flat portion FP3, and the first flat portion FP1, the second flat portion FP2, and the third flat portion FP3 may be seen as being separated from each other by the groove GR.

In an embodiment, as shown in FIG. 6, in an area where one pixel PXL is provided, a planar area of the connection portion CP may be smaller than a planer area of the flat portion FP. For example, the planar area of the connection portion CP may be about 20% or less, about 15% or less, or preferable, about 5% or less of the planar area of the flat portion FP.

In an embodiment, a first pixel through-hole PCNT1 and an auxiliary through-hole VCNT may be defined in the first flat portion FP1. At least a portion of a component (e.g., an electrode forming a transistor or a line connected thereto) constituting a first sub-pixel circuit SPC1 of the first sub-pixel SP1 may be exposed through the first pixel through-hole PCNT1. At least a portion of an auxiliary voltage line VL may be exposed through the auxiliary through-hole VCNT. The second power voltage, which is provided to the second power voltage node VSSN described with reference to FIG. 3, may be applied to the auxiliary voltage line VL.

In an embodiment, a second pixel through-hole PCNT2 may be defined in the second flat portion FP2. At least a portion of a component (e.g., an electrode forming a transistor or a line connected thereto) constituting a second sub-pixel circuit SPC2 of the second sub-pixel SP2 may be exposed through the second pixel through-hole PCNT2.

In an embodiment, a third pixel through-hole PCNT3 may be defined in the third flat portion FP3. At least a portion of a component (e.g., an electrode forming a transistor or a line connected thereto) constituting a third sub-pixel circuit SPC3 of the third sub-pixel SP3 may be exposed through the third pixel through-hole PCNT3.

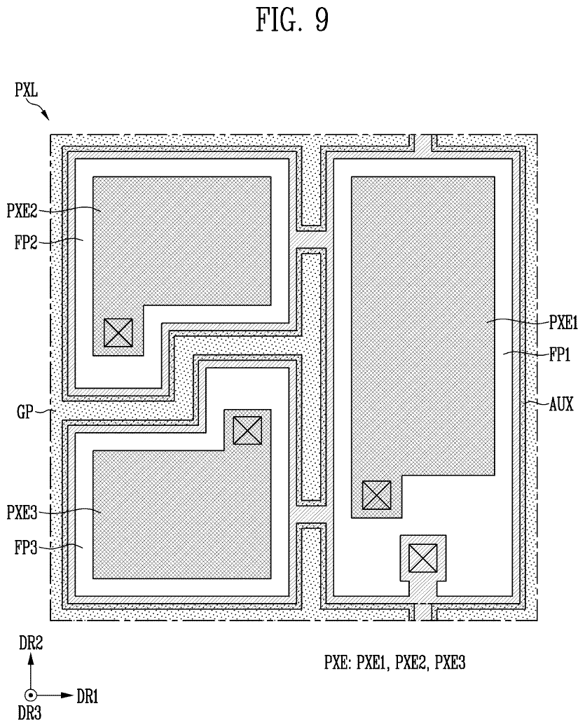

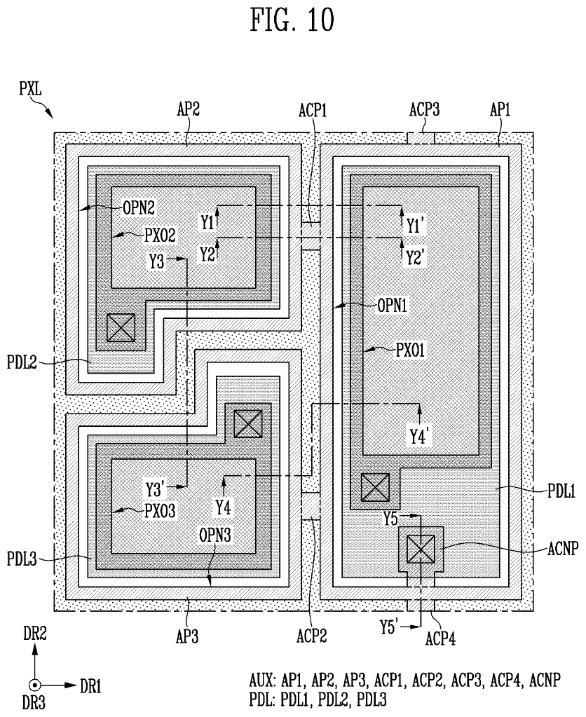

FIG. 9 is a plan view showing an auxiliary electrode AUX and a pixel electrode PXE included in the pixel PXL in addition to the components shown in FIG. 6. FIG. 10 is a plan view showing a pixel defining layer PDL included in the pixel PXL in addition to the components shown in FIG. 9.

Referring to FIG. 6, FIG. 9, and FIG. 10, the pixel PXL may include an auxiliary electrode AUX and a pixel electrode PXE disposed on the via-layer VIA and spaced apart from each other.

The auxiliary electrode AUX may include a polycrystalline (or crystalline) transparent conductive oxide (“TCO”). For example, the auxiliary electrode AUX may include a polycrystalline indium tin oxide (“p-ITO”). In an embodiment, the auxiliary electrode AUX may be a single-layer structure including the polycrystalline transparent conductive oxide.

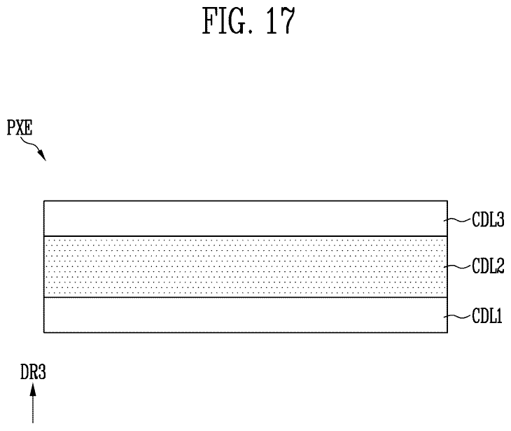

In an embodiment, the pixel electrode PXE may include a metal. The pixel electrode PXE may be a multi-layer structure including the metal. This will be described later with reference to FIG. 17.

In an embodiment, the auxiliary electrode AUX may include a first auxiliary electrode portion AP1, a second auxiliary electrode portion AP2, a third auxiliary electrode portion AP3, a first connection electrode portion ACP1, a second connection electrode portion ACP2, a third connection electrode portion ACP3, and a fourth connection electrode portion ACP4.

The first auxiliary electrode portion AP1 may be disposed in an area where the first sub-pixel SP1 is provided. The first auxiliary electrode portion AP1 may define a first opening OPN1 exposing a portion of the first flat portion FP1. In an embodiment, the first opening OPN1 may overlap the first pixel through-hole PCNT1 and the auxiliary through-hole VCNT in a plan view. The first auxiliary electrode portion AP1 may overlap a boundary between the first flat portion FP1 and the recessed portion GP in a plan view. The first auxiliary electrode portion AP1 may overlap a boundary between the first flat portion FP1 and the first connection portion CP1, a boundary between the first flat portion FP1 and the third connection portion CP3, and a boundary between the first flat portion FP1 and the fourth connection portion CP4 in a plan view.

The second auxiliary electrode portion AP2 may be disposed in an area where the second sub-pixel SP2 is provided. The second auxiliary electrode portion AP2 may be spaced apart from the first auxiliary electrode portion AP1. The second auxiliary electrode portion AP2 may define a second opening OPN2 exposing a portion of the second flat portion FP2. In an embodiment, the second opening OPN2 may overlap the second pixel through-hole PCNT2 in a plan view. The second auxiliary electrode portion AP2 may overlap a boundary between the second flat portion FP2 and the recessed portion GP in a plan view. The second auxiliary electrode portion AP2 may overlap a boundary between the second flat portion FP2 and the first connection portion CP1 in a plan view.

The third auxiliary electrode portion AP3 may be disposed in an area where the third sub-pixel SP3 is provided. The third auxiliary electrode portion AP3 may be spaced apart from the first and the second auxiliary electrode portions AP1 and AP2. The third auxiliary electrode portion AP3 may define a third opening OPN3 exposing a portion of the third flat portion FP3. In an embodiment, the third opening OPN3 may overlap the third pixel through-hole PCNT3 in a plan view. The third auxiliary electrode portion AP3 may overlap a boundary between the third flat portion FP3 and the recessed portion GP in a plan view. The third auxiliary electrode portion AP3 may overlap a boundary between the third flat portion FP3 and the second connection portion CP2 in a plan view.

The first connection electrode portion ACP1 may be disposed on the first connection portion CP1. The first connection electrode portion ACP1 may electrically connect the first auxiliary electrode portion AP1 and the second auxiliary electrode portion AP2 to each other. The first connection electrode portion ACP1 may cover an upper surface of the first connection portion CP1. The first connection electrode portion ACP1 may overlap a boundary between the first connection portion CP1 and the recessed portion GP in a plan view.

The second connection electrode portion ACP2 may be disposed on the second connection portion CP2 (See FIGS. 6 and 10). The second connection electrode portion ACP2 may electrically connect the first auxiliary electrode portion AP1 and the third auxiliary electrode portion AP3 to each other. The second connection electrode portion ACP2 may cover an upper surface of the second connection portion CP2. The second connection electrode portion ACP2 may overlap a boundary between the second connection portion CP2 and the recessed portion GP in a plan view.

The third connection electrode portion ACP3 may be disposed on the third connection portion CP3. The third connection electrode portion ACP3 may electrically connect the first auxiliary electrode portion AP1 and an auxiliary electrode AUX included in other pixel PXL adjacent to the pixel PXL in the second direction DR2. The third connection electrode portion ACP3 may cover an upper surface of the third connection portion CP3. The third connection electrode portion ACP3 may overlap a boundary between the third connection portion CP3 and the recessed portion GP in a plan view.

The fourth connection electrode portion ACP4 may be disposed on the fourth connection portion CP4. The fourth connection electrode portion ACP4 may electrically connect the first auxiliary electrode portion AP1 and an auxiliary electrode AUX included in other pixel PXL adjacent to the pixel PXL in a direction opposite to the second direction DR2. The fourth connection electrode portion ACP4 may cover an upper surface of the fourth connection portion CP4. The fourth connection electrode portion ACP4 may overlap a boundary between the fourth connection portion CP4 and the recessed portion GP in a plan view.

In an embodiment, the auxiliary electrode AUX may further include an auxiliary voltage receiving portion ACNP. The auxiliary voltage receiving portion ACNP may be extended from the first auxiliary electrode portion AP1 to the auxiliary through-hole VCNT. For example, the auxiliary voltage receiving portion ACP may be seen as to extend from the first auxiliary electrode portion AP1 toward the first pixel electrode PXE1. The auxiliary voltage receiving portion ACP may overlap the auxiliary through-hole VCNT in a plan view, and may fill the auxiliary through-hole VCNT. Accordingly, the first auxiliary electrode portion AP1 may be electrically connected to the auxiliary voltage line VL described with reference to FIG. 8 through the auxiliary voltage receiving portion ACNP to receive the second power voltage.

The first auxiliary electrode portion AP1, the second auxiliary electrode portion AP2, the third auxiliary electrode portion AP3, the first connection electrode portion ACP1, the second connection electrode portion ACP2, the third connection electrode portion ACP3, the fourth connection electrode portion ACP4, and the auxiliary voltage receiving portion ACNP may be integrally formed. Accordingly, the second power voltage transmitted to the auxiliary voltage receiving portion ACNP through the auxiliary voltage line VL may be applied to the first auxiliary electrode portion AP1, the second auxiliary electrode portion AP2, the third auxiliary electrode portion AP3, the first connection electrode portion ACP1, the second connection electrode portion ACP2, the third connection electrode portion ACP3, and the fourth connection electrode portion ACP4.

The pixel electrode PXE may include a first pixel electrode PXE1, a second pixel electrode PXE2, and a third pixel electrode PXE3.

The first pixel electrode PXE1 may be disposed in an area where the first sub-pixel SP1 is provided. The first pixel electrode PXE1 may function as the pixel electrode PXE of the first sub-pixel SP1.

In an embodiment, the first pixel electrode PXE1 may be disposed on the first flat portion FP1 exposed by the first opening OPN1. The first pixel electrode PXE1 may be spaced apart from the auxiliary electrode AUX. The first pixel electrode PXE1 may overlap the first pixel through-hole PCNT1 in a plan view, and may fill the first pixel electrode PCNT1. Accordingly, the first pixel electrode PXE1 may be electrically connected to at least a portion of the component (e.g., an electrode forming a transistor or a line connected thereto) constituting the first sub-pixel circuit SPC1 described with reference to FIG. 8.

The second pixel electrode PXE2 may be spaced apart from the first pixel electrode PXE1. The second pixel electrode PXE2 may be disposed in an area where the second sub-pixel SP2 is provided. The second pixel electrode PXE2 may function as the pixel electrode PXE of the second sub-pixel SP2.

In an embodiment, the second pixel electrode PXE2 may be disposed on the second flat portion FP2 exposed by the second opening OPN2. The second pixel electrode PXE2 may be spaced apart from the auxiliary electrode AUX. The second pixel electrode PXE2 may overlap the second pixel through-hole PCNT2 in a plan view, and may fill the second pixel through-hole PCNT2. Accordingly, the second pixel electrode PXE2 may be electrically connected to the component (e.g., an electrode forming a transistor or a line connected thereto) constituting the second sub-pixel circuit SPC2 described with reference to FIG. 8.

The third pixel electrode PXE3 may be spaced apart from the first and the second pixel electrodes PXE1 and PXE2. The third pixel electrode PXE3 may be disposed in an area where the third sub-pixel SP3 is provided. The third pixel electrode PXE3 may function as the pixel electrode PXE of the third sub-pixel SP3.

In an embodiment, the third pixel electrode PXE3 may be disposed on the third flat portion FP3 exposed by the third opening OPN3. The third pixel electrode PX3 may be spaced apart from the auxiliary electrode AUX. The third pixel electrode PXE3 may overlap the third pixel through-hole PCNT3 in a plan view, and may fill the third pixel through-hole PCNT3. Accordingly, the third pixel electrode PXE3 may be electrically connected to the component (e.g., an electrode forming a transistor or a line connected thereto) constituting the third sub-pixel circuit SPC3 described with reference to FIG. 8.

The pixel PXL may include a pixel defining layer PDL. The pixel defining layer PDL may include organic insulating material and/or inorganic insulating material.

In an embodiment, the pixel defining layer PDL may include a first pixel defining layer PDL1, a second pixel defining layer PDL2, and a third pixel defining layer PDL3.

The first pixel defining layer PDL1 may be disposed in an area where the first sub-pixel SP1 is provided. The first pixel defining layer PDL1 may be disposed on the first flat portion FP1 and the first pixel electrode PXE1 in the first opening OPN1. The first pixel defining layer PDL1 may define a first pixel opening PXO1 exposing at least a portion of the first pixel electrode PXE1. In this case, a light emitting area of the first sub-pixel SP1 may be seen as defined by the first pixel opening PXO1.

The second pixel defining layer PDL2 may be disposed in an area where the second sub-pixel SP2 is provided. The second pixel defining layer PDL2 may be disposed on the second flat portion FP2 and the second pixel electrode PXE2 in the second opening OPN2. The second pixel electrode PDL2 may define a second pixel opening PXO2 exposing at least a portion of the second pixel electrode PXE2. In this case, a light emitting area of the second sub-pixel SP2 may be seen as defined by the second pixel opening PXO2.

The third pixel defining layer PDL3 may be disposed in an area where the third sub-pixel SP3 is provided. The third pixel defining layer PDL3 may be disposed on the third flat portion FP3 and the third pixel electrode PXE3 in the third opening OPN3. The third pixel electrode PDL3 may define a third pixel opening PXO3 exposing at least a portion of the third pixel electrode PXE3. In this case, a light emitting area of the third sub-pixel SP3 may be seen as defined by the third pixel opening PXO3.

In FIG. 10, an embodiment that first pixel defining layer PDL1 is disposed in the first opening OPN1, the second pixel defining layer PDL2 is disposed in the second opening OPN2, and the third pixel defining layer PDL3 is disposed in the third opening OPN3 is shown. In other words, in FIG. 10, an embodiment that the first pixel defining layer PDL1 is spaced apart from the first auxiliary electrode portion AP1, the second pixel defining layer PDL2 is spaced apart from the second auxiliary electrode portion AP2, and the third pixel defining layer PDL3 is spaced apart from the third auxiliary electrode portion AP3 is shown.

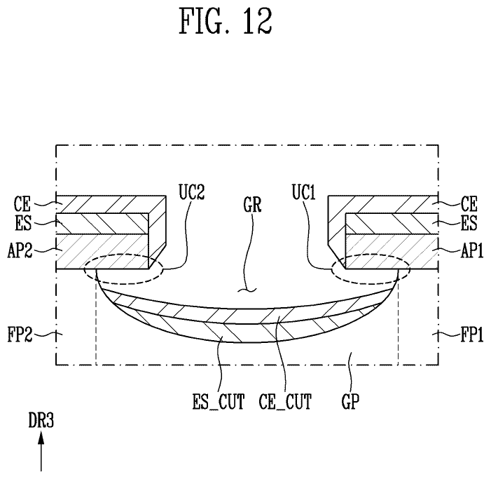

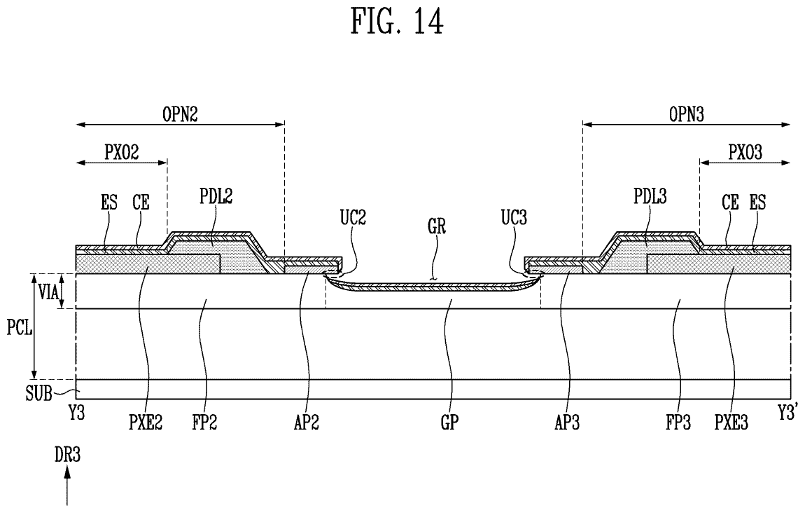

However, the present disclosure is not limited thereto. In an embodiment, the first pixel defining layer PDL1 may cover at least a portion of the first auxiliary electrode portion AP1 adjacent to the first opening OPN1. In the above-described embodiment, a side surface of the first auxiliary electrode portion AP1 adjacent to a first undercut (UC1, refer to FIG. 12) may not be covered by the first pixel defining layer PDL1. In an embodiment, the second pixel defining layer PDL2 may cover at least a portion of the second auxiliary electrode portion AP2 adjacent to the second opening OPN2. In the above-described embodiment, a side surface of the second auxiliary electrode portion AP2 adjacent to a second undercut (UC2, refer to FIG. 12) may not be covered by the second pixel electrode PDL2. In an embodiment, the third pixel defining layer PDL3 may cover at least a portion of the third auxiliary electrode portion AP3 adjacent to the third opening OPN3. In the above-described embodiment, a side surface of the third auxiliary electrode portion AP3 adjacent to a third undercut (UC3, refer to FIG. 14) may not be covered by the third pixel defining layer PDL3.

The pixel PXL may further include a light emitting structure ES and a common electrode CE. The light emitting structure ES may be disposed on the via-layer VIA, the auxiliary electrode AUX, the pixel electrode PXE, and the pixel defining layer PDL. The common electrode CE may be disposed on the light emitting structure ES. The common electrode CE may be connected to the second power voltage node VSSN described with reference to FIG. 3 to receive the second power voltage.

The light emitting structure ES and the common electrode CE may be disposed on the entirety of an area where the pixel PXL shown in FIG. 10 is provided. In this case, the light emitting structure ES and the common electrode CE may be disconnected in some areas by the recessed portion GP defining the groove GR and by the auxiliary electrode AUX.

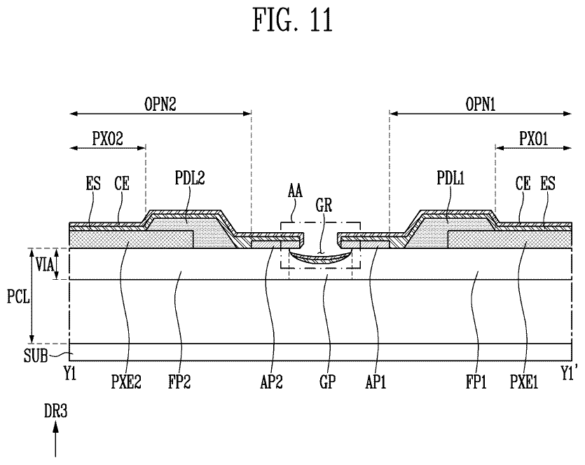

Hereinafter, an embodiment in which the light emitting structure ES and the common electrode CE are disconnected in some areas will be described in more detail with reference to FIGS. 11 to 16.

FIG. 11 is a cross-sectional view taken along line Y1-Y1′ of FIG. 10. FIG. 12 is a cross-sectional view enlarging an area AA of FIG. 11.

Referring to FIG. 11 and FIG. 12, the groove GR may be defined in the recessed portion GP between the first flat portion FP1 and the second flat portion FP2.

The first auxiliary electrode portion AP1 may overlap the boundary between the first flat portion FP1 and the recessed portion GP in a plan view, and a portion of the first auxiliary electrode portion AP1 may overlap a portion of the groove GR in a plan view. Accordingly, a first undercut UC1 may be defined by the first auxiliary electrode portion AP1 and the groove GR adjacent to the first flat portion FP1.

The second auxiliary electrode portion AP2 may overlap the boundary between the second flat portion FP2 and the recessed portion GP in a plan view, and a portion of the second auxiliary electrode portion AP2 may overlap a portion of the groove GR in a plan view. Accordingly, a second undercut UC2 may be defined by the second auxiliary electrode portion AP2 and the groove GR adjacent to the second flat portion FP2.

The light emitting structure ES disposed on the entirety of the via-layer VIA, the auxiliary electrode AUX, the pixel electrode PXE, and the pixel defining layer PDL may be disconnected by the first undercut UC1 and the second undercut UC2. Specifically, the light emitting structure ES may be disconnected by a step caused by the first undercut UC1 and the second undercut UC2, so that a first disconnection portion ES_CUS may be disposed in the groove GR. In an embodiment, the first disconnection portion ES_CUT may be physically separated from the light emitting structure ES.

The common electrode CE disposed on the entirety of the light emitting structure ES may be disconnected by the first undercut UC1 and the second undercut UC2. Specifically, the common electrode CE may be disconnected by the step caused by the first undercut UC1 and the second undercut UC2, so that a second disconnection portion CE_CUT may be disposed on the disconnection portion ES_CUT of the light emitting structure ES in the groove GR. In an embodiment, the second disconnection portion ES_CUT may be physically separated from the common electrode CE.

In an embodiment, a portion of the first pixel electrode PXE overlapping the first pixel opening PXO1, a portion of the light emitting structure ES overlapping the first pixel opening PXO1, and a portion of the common electrode CE overlapping the first pixel opening PXO1 in a plan view may function as the light emitting element LD (refer to FIG. 2) of the first sub-pixel SP1.

In an embodiment, a portion of the second pixel electrode PXE2 overlapping the second pixel opening PXO2, a portion of the light emitting structure ES overlapping the second pixel opening PXO2, and a portion of the common electrode CE overlapping the second pixel opening PXO2 in a plan view may function as the light emitting element LD (refer to FIG. 2) of the second sub-pixel SP2.

In the above-described embodiments, since the light emitting structure ES and the common electrode CE are disconnected between the first pixel opening PXO1 and the second pixel opening PXO2 by the first undercut UC1 and the second undercut UC2, generation of a lateral leakage current between the first sub-pixel SP1 and the second sub-pixel SP2 may be effectively prevented.

In an embodiment, the common electrode CE may electrically contact the auxiliary electrode AUX. Specifically, the common electrode CE may electrically contact each of the side surface of the first auxiliary electrode portion AP1 adjacent to the first undercut UC1 and the side surface of the second auxiliary electrode portion AP2 adjacent to the second undercut UC2. In this case, the light emitting structure ES may be disposed between the common electrode CE and each of an upper surface of the first auxiliary electrode portion AP1 adjacent to the side surface of the first auxiliary electrode portion AP1 and an upper surface of the second auxiliary electrode portion AP2 adjacent to the side surface of the second auxiliary electrode portion AP2.

Generally, the common electrode CE may be disposed on the entirety of the display area DA of FIG. 3 and may be connected to the power line PL in the non-display area NDA to receive the second power voltage. In this case, there may be a problem that the second power voltage drops (IR drop) in a center of the display area DA due to factors such as resistance of a material constituting the common electrode CE.

In the present disclosure, as mentioned above, the common electrode CE electrically contacting the auxiliary electrode AUX may receive the second power voltage through the auxiliary electrode AUX. Accordingly, even in areas where voltage drop of the second power voltage may be a problem, such as the center of the display area DA (refer to FIG. 3), the second power voltage can be transmitted to the common electrode CE through the auxiliary electrode AUX. Therefore, the problem of voltage drop of the second power voltage may not substantially occur.

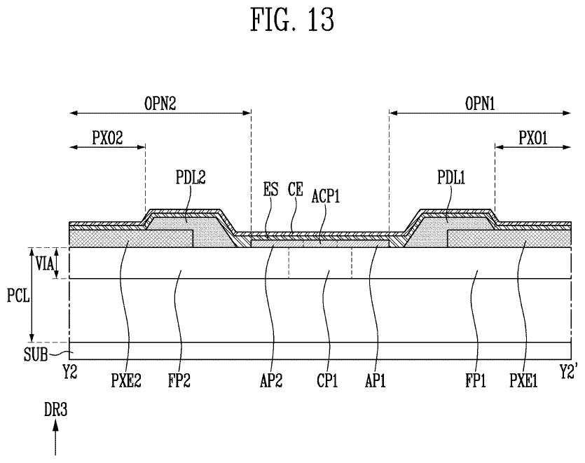

FIG. 13 is a cross-sectional view taken along line Y2-Y2′ of FIG. 10.

Referring to FIG. 13, the first auxiliary electrode portion AP1 and the second auxiliary electrode portion AP2 may be electrically connected to each other through the first connection electrode portion ACP1 on the first connection portion CP1 between the first flat portion FP1 and the second flat portion FP2. Accordingly, the second power voltage applied to the auxiliary voltage receiving portion ACNP may be transmitted to the second auxiliary electrode portion AP2 through the first auxiliary electrode portion AP1 and the first connection electrode portion ACP1.

In an embodiment, in an area overlapping the first connection portion CP1 (or the first connection electrode portion ACP1), compared to the embodiment described with reference to FIGS. 11 and 12, the light emitting structure ES and the common electrode CE may be disposed continuously without being substantially disconnected.

In the above-described embodiment, the planar area of the connection portion CP may be smaller than the planar area of the flat portion FP (e.g., the planar area of the connection portion CP may be about 20% or less, about 15% or less, or preferable, about 5% or less of the planar area of the flat portion FP), so that a planar area of an area in which the light emitting structure ES and the common electrode CE are continuously disposed without being substantially disconnected between the first flat portion FP1 and the second flat portion FP2 may be relatively small. Accordingly, even if there is the area in which the light emitting structure ES and the common electrode CE are continuously disposed without being substantially disconnected between the first flat portion FP1 and the second flat portion FP2 as shown in FIG. 13, a lateral leakage current may not substantially occur between the first sub-pixel SP1 and the second sub-pixel SP2.

FIG. 14 is a cross-sectional view taken along line Y3-Y3′ of FIG. 10.

Referring to FIG. 14, the groove GR may be defined in the recessed portion GP between the second flat portion FP2 and the third flat portion FP3.

The second auxiliary electrode portion AP2 may overlap the boundary between the second flat portion FP2 and the recessed portion GP in a plan view, and a portion of the second auxiliary electrode portion AP2 may overlap a portion of the groove GR in a plan view. Accordingly, the second undercut UC2 may be defined by the second auxiliary electrode portion AP2 and the groove GR adjacent to the second flat portion FP2, as described above with reference to FIGS. 11 and 12.

The third auxiliary electrode portion AP3 may overlap the boundary between the third flat portion FP3 and the recessed portion GP in a plan view, and a portion of the third auxiliary electrode portion AP3 may overlap a portion of the groove GR in a plan view. Accordingly, a third undercut UC3 may be defined by the third auxiliary electrode portion AP3 and the groove GR adjacent to the third flat portion FP3.

The light emitting structure ES disposed on the entirety of the via-layer VIA, the auxiliary electrode AUX, the pixel electrode PXE, and the pixel defining layer PDL may be disconnected by the second undercut UC2 and the third undercut UC3. Likewise, the common electrode CE disposed on the entirety of the light emitting structure ES may be disconnected by the second undercut UC2 and the third undercut UC3.

In an embodiment, a portion of the third pixel electrode PXE3 overlapping the third pixel opening PXO3, a portion of the light emitting structure ES overlapping the third pixel opening PXO3, and a portion of the common electrode CE overlapping the third pixel opening PXO3 in a plan view may function as the light emitting element LD (refer to FIG. 2) of the third sub-pixel SP3.

In the above-described embodiments, since the light emitting structure ES and the common electrode CE are disconnected between the second pixel opening PXO2 and the third pixel opening PXO3 by the second undercut UC2 and the third undercut UC3, generation of a lateral leakage current between the second sub-pixel SP2 and the third sub-pixel SP3 may be effectively prevented.

In an embodiment, the common electrode CE may electrically contact the side surface of the second auxiliary electrode portion AP2 adjacent to the second undercut UC2. This may be described in the same way as described with reference to FIGS. 11 and 12.

In an embodiment, the common electrode CE may electrically contact the side surface of the third auxiliary electrode portion AP3 adjacent to the third undercut UC3. In this case, the light emitting structure ES may be disposed between the common electrode CE and an upper surface of the third auxiliary electrode portion AP3 adjacent to the side surface of the third auxiliary electrode portion AP3. That is, the common electrode CE may electrically contact a portion of the third auxiliary electrode AP3 that is not covered by the light emitting structure ES.

In the above-described embodiment, as described with reference to FIGS. 11 and 12, since the common electrode CE electrically contacts each of the second auxiliary electrode portion AP2 and the third auxiliary electrode portion AP3 to receive the second power voltage, the voltage drop of the second power voltage may not substantially occur.

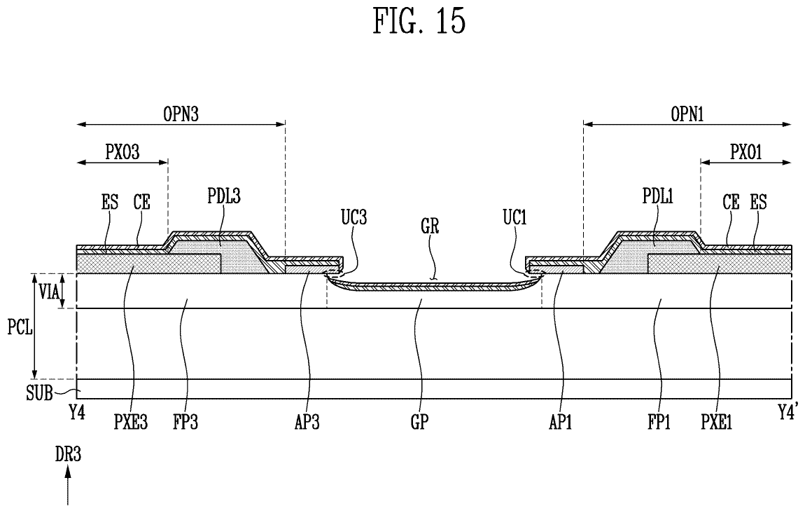

FIG. 15 is a cross-sectional view taken along line Y4-Y4′ of FIG. 10.

Referring to FIG. 15, the groove GR may be defined in the recessed portion GP between the first flat portion FP1 and the third flat portion FP3.

The first auxiliary electrode portion AP1 may overlap the boundary between the first flat portion FP1 and the recessed portion GP in a plan view, and a portion of the first auxiliary electrode AP1 may overlap a portion of the groove GR in a plan view. Accordingly, the first undercut UC1 may be defined by the first auxiliary electrode portion AP1 and the groove GR adjacent to the first flat portion FP1, as described above with reference to FIGS. 11 and 12.

The third auxiliary electrode portion AP3 may overlap the boundary between the third flat portion FP3 and the recessed portion GP in a plan view, and a portion of the third auxiliary electrode portion AP3 may overlap a portion of the groove GR in a plan view. Accordingly, the third undercut UC3 may be defined by the third auxiliary electrode portion AP3 and the groove GR adjacent to the third flat portion FP3, as described with reference to FIG. 14.

The light emitting structure ES disposed on the entirety of the via-layer VIA, the auxiliary electrode AUX, the pixel electrode PXE, and the pixel defining layer PDL may be disconnected by the first undercut UC1 and the third undercut UC3. Likewise, the common electrode CE disposed on the entirety of the light emitting structure ES may be disconnected by the first undercut UC1 and the third undercut UC3. Accordingly, generation of a lateral leakage current between the first sub-pixel SP1 and the third sub-pixel SP3 may be effectively prevented.

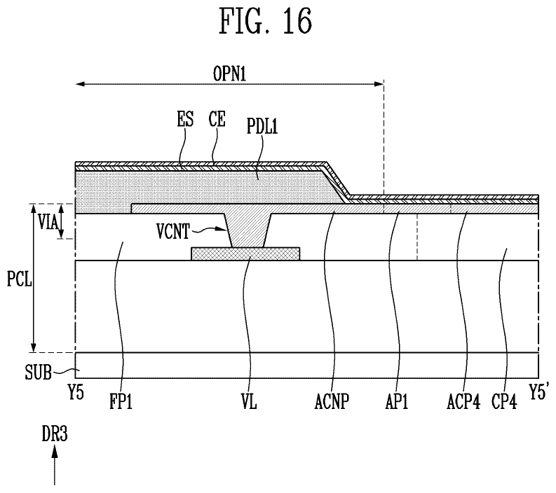

FIG. 16 is a cross-sectional view taken along line Y5-Y5′ of FIG. 10.

Referring to FIG. 16, the auxiliary voltage receiving portion ACNP may be electrically connected to the auxiliary voltage line VL through the auxiliary through-hole VCNT in the first opening OPN1. In this case, the second power voltage applied to the auxiliary voltage receiving portion ACNP through the auxiliary voltage line VL may be transmitted to the first auxiliary electrode portion AP1.

FIG. 17 is a cross-sectional view illustrating an embodiment of a pixel electrode.

Referring to FIG. 17, the pixel electrode PXE may be a multi-layer structure including a first pixel electrode layer CDL1, a second pixel electrode layer CDL2, and a third pixel electrode layer CLD3 sequentially stacked along the third direction DR3.

In an embodiment, the first pixel electrode layer CDL1 and the third pixel electrode layer CDL3 may include transparent conductive oxide (TCO).

In the above-described embodiment, the first pixel electrode layer CDL1 and the third pixel electrode layer CDL3 may include a different type of transparent conductive oxide from the auxiliary electrode AUX. For example, the first pixel electrode layer CDL1 and the third pixel electrode layer CDL3 may include an amorphous ITO (“a-ITO”), indium zinc oxide (“IZO”), and/or ZnO, and the auxiliary electrode AUX may include a polycrystalline ITO (p-ITO).

In an embodiment, the second pixel electrode layer CDL2 may include metal. For example, the second pixel electrode layer CDL2 may include silver (Ag), but embodiments are not limited thereto. Since the second pixel electrode layer CDL2 includes a metal, the pixel electrode PXE may perform a function of reflecting light. Therefore, light generated from the light emitting structure ES disposed on the pixel electrode PXE may be reflected by the pixel electrode PXE and effectively provided to the user of the display device DD.

As such, the pixel electrode PXE and the auxiliary electrode AUX may be disposed on the via-layer VIA (or directly on the via-layer VIA), but may include different materials from each other. And, unlike the auxiliary electrode AUX which may be a single-layer structure, the pixel electrode PXE may be a multi-layer structure.

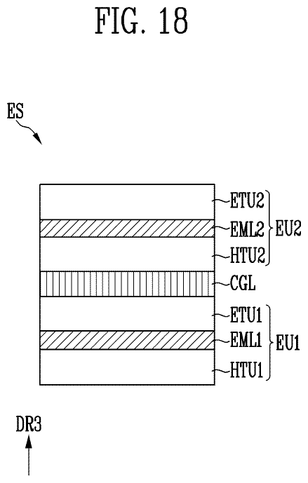

FIG. 18 is a cross-sectional view illustrating an embodiment of a light emitting structure.

Referring to FIG. 18, the light emitting structure ES may have a tandem structure in which first and second light emitting units EU1 and EU2 are stacked.

Each of the first and the second light emitting units EU1 and EU2 may include at least one light emitting layer that generates light depending on applied current.

The first light emitting unit EU1 may include a first light emitting layer EML1, a first electron transport unit ETU1, and a first hole transport unit HTU1. The first light emitting layer EML1 may be disposed between the first electron transport unit ETU1 and the first hole transport unit HTU1.

The second light emitting unit EU2 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and the second hole transport units HTU1 and HTU2 may include at least one of a hole injection layer and a hole transport layer, and may further include a hole buffer layer and/or an electron blocking layer. The first and the second hole transport units HTU1 and HTU2 may have same components or different components.

Each of the first and the second electron transport units ETU1 and ETU2 may include at least one of an electron injection layer and an electron transport layer, and may further include an electron buffer layer and/or an electron blocking layer. The first and the second electron transport units ETU1 and ETU2 may have same components or different components.

A connecting layer, which may be provided in a form of a charge generation layer CGL, may be disposed between the first light emitting unit EU1 and the second light emitting unit EU2 to connect the first light emitting unit EU1 and the second light emitting unit EU2. In embodiments, the charge generation layer CGL may have a stacked structure of a p-dopant layer and a n-dopant layer. For example, the p-dopant layer may include p-type dopant such as HAT-CN, TCNQ, and/or NDP-9, and the n-dopant layer may include alkali metals, alkaline earth metals, lanthanide-based metals, and/or combinations thereof. However, embodiments art not limited thereto.

In embodiments, the first light emitting layer EML1 and the second light emitting layer EML2 may generate light of different colors. The light emitted from each of the first light emitting layer EML1 and the second light emitting layer EML2 may be mixed and visually recognized as white light. For example, the first light emitting layer EML1 may generate light of blue color, and the second light emitting layer EML2 may generate light of yellow color. In embodiments, the second light emitting layer EML2 may include a structure in which a first sub-light emitting layer configured to generate light of red color and a second sub-light emitting layer configured to generate light of green color are stacked. The light of red color and the light of green color may be mixed and provided as light of yellow color. In this case, a intermediate layer configured to perform a function of transporting holes and/or a function of blocking transporting of electrons may be further disposed between the first and the second sub-light emitting layers.

In another embodiments, the first light emitting layer EML1 and the second light emitting layer EML2 may generate light of same color.

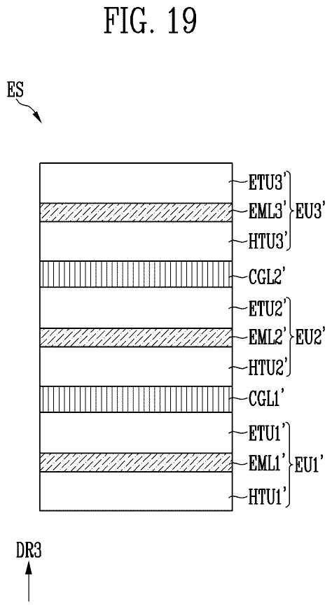

FIG. 19 is a cross-sectional view illustrating another embodiment of a light emitting structure.

Referring to FIG. 19, a light emitting structure ES may have a tandem structure in which first to third light emitting units EU1′, EU2′, and EU3′.

Each of the first to third light emitting units EU1′, EU2′, and EU3′ may include a light emitting layer that generates light depending on applied current.

The first light emitting unit EU1′ may include a first light emitting layer EML1′, a first electron transport unit ETU1′, and a first hole transport unit HTU1′. The first light emitting layer EML1′ may be disposed between the first electron transport unit ETU1′ and the first hole transport unit HTU1′.

The second light emitting unit EU2′ may include a second light emitting layer EML2′, a second electron transport unit ETU2′, and a second hole transport unit HTU2′. The second light emitting layer EML2′ may be disposed between the second electron transport unit ETU2′ and the second hole transport unit HTU2′.

The third light emitting unit EU3′ may include a third light emitting layer EML3′, a third electron transport unit ETU3′, and a third hole transport unit HTU3′. The third light emitting layer EML3′ may be disposed between the third electron transport unit ETU3′ and the third hole transport unit HTU3′.

Each of the first to third hole transport units HTU1′, HTU2′, and HTU3′ may include at least one of a hole injection layer and a hole transport layer, and may further include a hole buffer layer and/or an electron blocking layer. The first to third hole transport units HTU1′, HTU2′, and HTU3′ may have same components or different components.

Each of the first to third electron transport units ETU1′, ETU2′, and ETU3′ may include at least one of an electron injection layer and an electron transport layer, and may further include an electron buffer layer and/or an electron blocking layer. The first to third electron transport units ETU1′, ETU2′, and ETU3′ may have same components or different components.

A first charge generation layer CGL1′ may be disposed between the first light emitting unit EU1′ and the second light emitting unit EU2′. A second charge generation layer CGL2′ may be disposed between the second light emitting unit EU2′ and the third light emitting unit EU3′.

In embodiments, the first to third light emitting layers EML1′, EML2′, and EML3′ may generate light of different colors. The light emitted from each of the first to third light emitting layers EML1′, EML2′, and EML3′ may be mixed and visually recognized as white light. For example, the first light emitting layer EML1′ may generate light of blue color, the second light emitting layer EML2′ may generate light of green color, and the third light emitting layer EML3′ may generate light of red color.

In another embodiments, two or more of the first to third light emitting layers EML1′, EML2′, and EML3′ may generate light of same color.

Hereinafter, a method of manufacturing the display device DD including the pixel PXL, which has been described with reference to FIGS. 6 to 19, will be described. Hereinafter, description of contents overlapping with those described with reference to FIGS. 1 to 19 may be omitted.

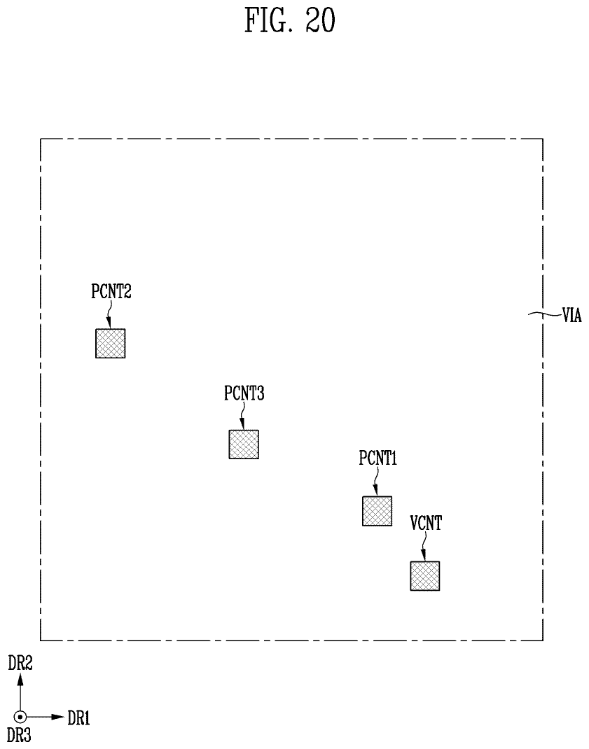

FIGS. 20 to 37 are diagrams illustrating a method of manufacturing the pixel of FIG. 10.

Referring to FIG. 20, a pixel defining layer PCL including a via-layer VIA may be formed. This step may include forming the first to third pixel through-holes PCNT1, PCNT2, and PCTN3 and the auxiliary through-hole VCNT described with reference to FIG. 6 and FIG. 8 in the via-layer VIA.

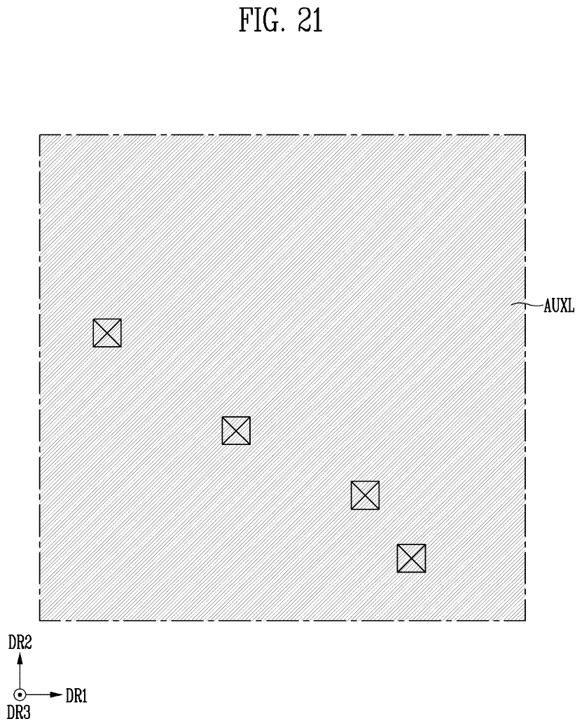

Referring to FIG. 21, an auxiliary electrode layer AUXL may be formed on the entirety of the via-layer VIA. In an embodiment, the auxiliary electrode layer AUXL may include an amorphous transparent conductive oxide. For example, the auxiliary electrode layer AUXM may include an amorphous ITO (a-ITO).

Unlike a polycrystalline (or crystalline) transparent conductive oxide, the amorphous transparent conductive oxide may be easily removed by an etchant during a wet etching process. In this case, a mask (e.g., patterned photoresist material) may be used in the above-described wet etching process to block contact between the amorphous transparent conductive oxide and the etchant in some areas, thereby patterning the amorphous transparent conductive oxide into a desired shape.

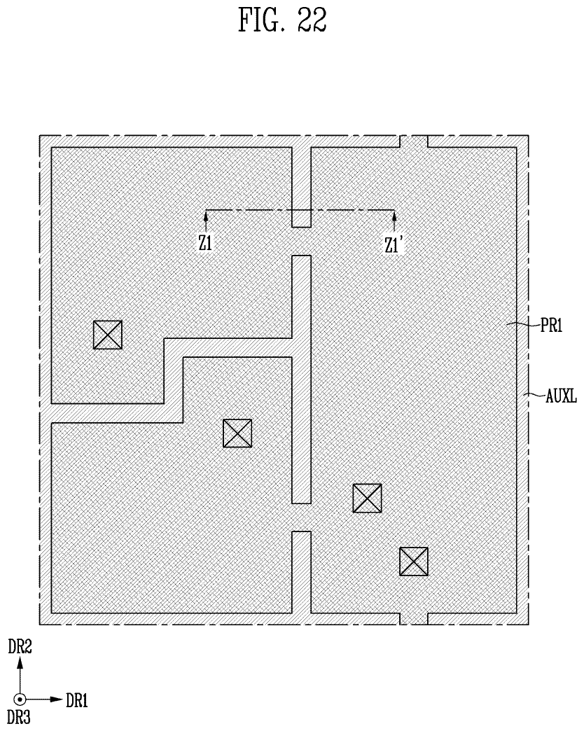

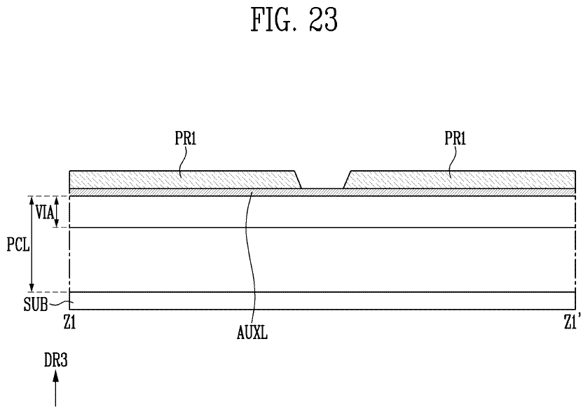

Referring to FIG. 22 and FIG. 23, a first photoresist pattern PR1 may be formed on the auxiliary electrode layer AUXL. In a plan view, an edge of the first photoresist pattern PR1 may substantially coincide with an edge of the auxiliary electrode AUX described with reference to FIG. 9 and FIG. 10.

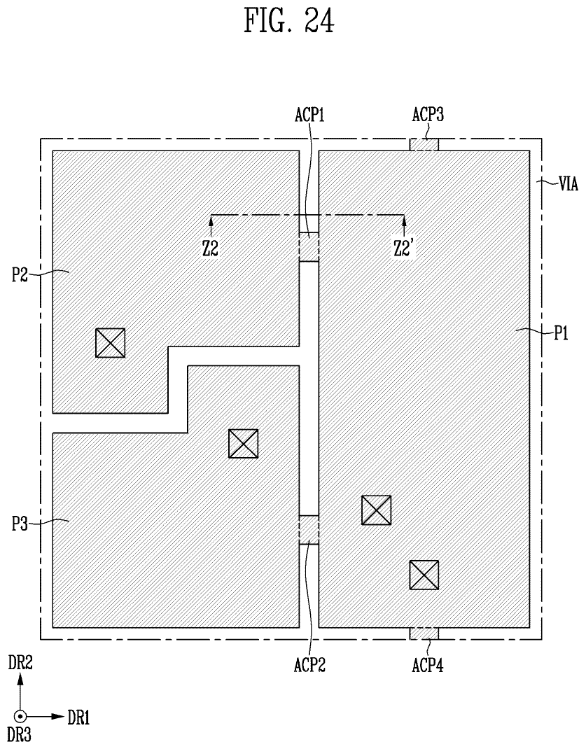

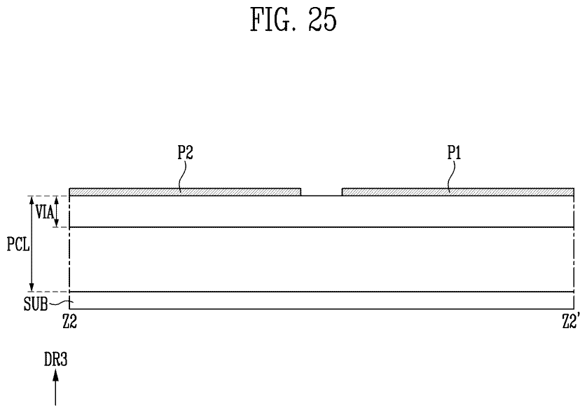

Referring to FIG. 24 and FIG. 25, the auxiliary electrode layer AUXL may be wet-etched by using the first photoresist pattern PR1 as a mask, and then the first photoresist pattern PR1 may be removed. Accordingly, in the auxiliary electrode layer AUXL of FIG. 21, a portion that overlaps the first photoresist pattern PR1 of FIG. 22 in a plan view may remain, and a portion that does not overlap the first photoresist pattern PR1 of FIG. 22 in a plan view may be removed.

In this step, a remaining portion of the auxiliary electrode layer AUXL after the wet-etching may include a first portion P1, a second portion P2, a third portion P3, a first connection electrode portion ACP1, a second connection electrode portion ACP2, a third connection electrode portion ACP3, and a fourth connection electrode portion ACP4.

The first portion P1 may be described in the same way as the first auxiliary electrode portion AP1 described with reference to FIG. 9 and FIG. 10, except that the first opening OPN1 is not defined.

The second portion P2 may be described in the same way as the second auxiliary electrode portion AP2 described with reference to FIG. 9 and FIG. 10, except that the second opening OPN2 is not defined.

The third portion P2 may be described in the same way as the third auxiliary electrode portion AP3 described with reference to FIG. 9 and FIG. 10, except that the third opening OPN3 is not defined.

The first to fourth connection electrode portions ACP1, ACP2, ACP3, and ACP4 may be described in the same way as described with reference to FIG. 9 and FIG. 10.

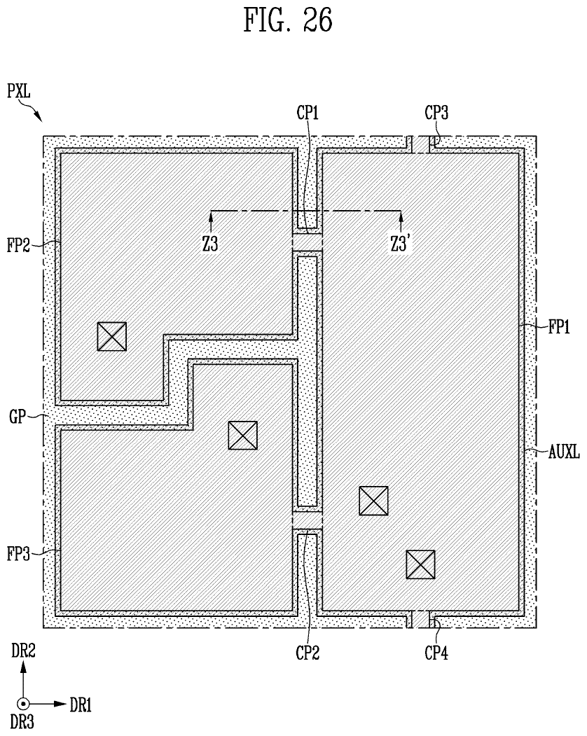

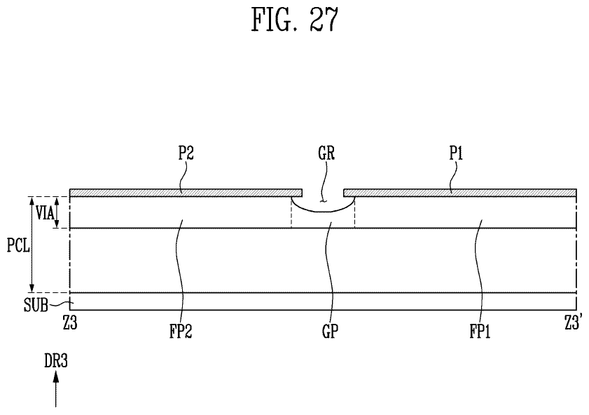

Referring to FIG. 26 and FIG. 27, the via-layer VIA may be ashed by using the auxiliary electrode layer AUXL after the wet-etching process described with reference to FIG. 24 and FIG. 25.

Accordingly, a groove GR may be formed in the via-layer VIA. In this step, the via-layer VIA in which the groove GR is formed may be described in the same way as described with reference to FIGS. 6 to 8.

That is, the via-layer VIA ashed in this step may include a raised portion PP and a recessed portion GP, the raised portion FP may include a flat portion FP and a connection portion CP, the flat portion FP may include first to third flat portions FP1, FP2, and FP3, and the connection portion CP may include first to fourth connection portions CP1, CP2, CP3, and CP4.

In an embodiment, in this step, the auxiliary electrode layer AUXL may cover entire of the raised portion PP of the via-layer VIA.

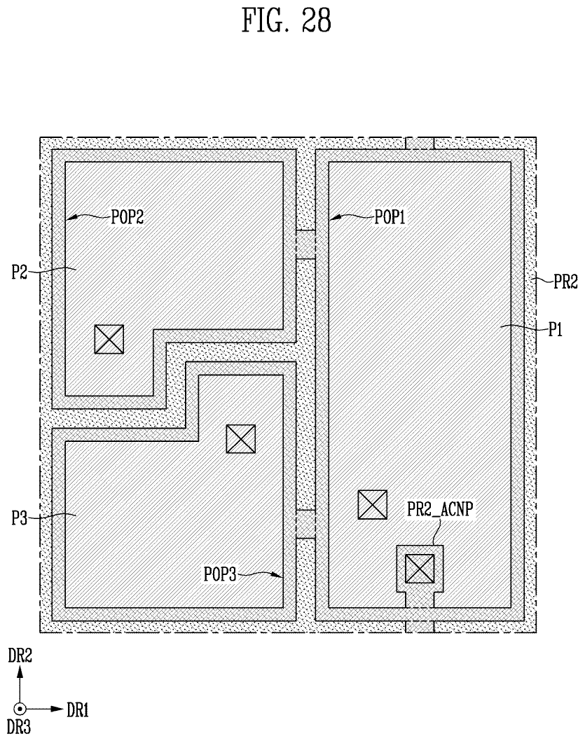

Referring to FIG. 28, a second photoresist pattern PR2 may be formed on the via-layer VIA and the auxiliary electrode layer AUXL.

The second photoresist pattern PR2 may include a first photoresist opening POP1, a second photoresist opening POP2, and a third photoresist opening POP3.

The first photoresist opening POP1 may correspond to the first opening OPN1 described with reference to FIG. 9 and FIG. 10, the second photoresist opening POP2 may correspond to the second opening OPN2 described with reference to FIG. 9 and FIG. 10, and the third photoresist opening POP3 may correspond to the third opening OPN3 described with reference to FIG. 9 and FIG. 10.

In this step, the second photoresist pattern PR2 may include an extended pattern PR2_ACNP. The extended pattern PR2_ACNP may be disposed in the first photoresist opening POP1, and may correspond to the auxiliary voltage receiving portion ACNP with reference to FIG. 9 and FIG. 10.

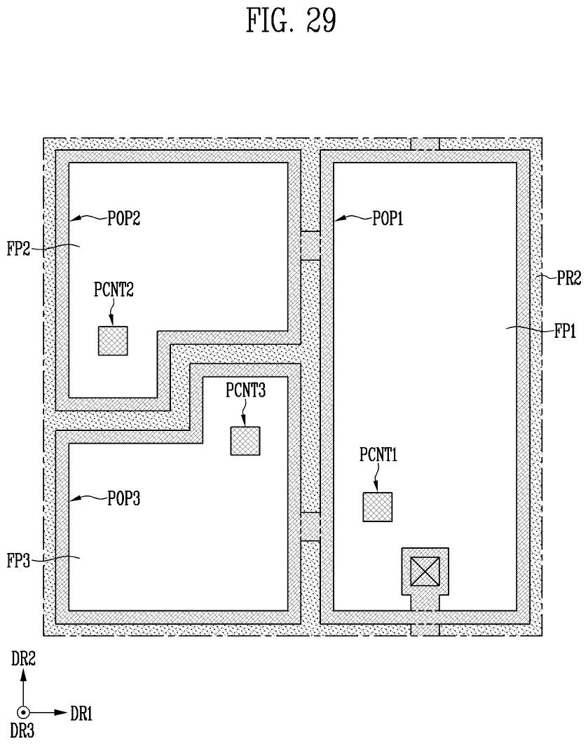

Referring to FIG. 29, the auxiliary electrode layer AUXL may be wet-etched by using the second photoresist pattern PR2 as a mask.

In this step, a portion that does not overlap the extended pattern PR2_ACNP among the first portion P1 overlapping the first photoresist opening POP1, a second portion P2 overlapping the second photoresist opening POP2, and a third portion P3 overlapping the third photoresist opening POP3 in a plan view may be removed by the etching.

Accordingly, a portion of the first flat portion FP1, a portion of the second flat portion FP2, and a portion of the third flat portion FP3 may be exposed.

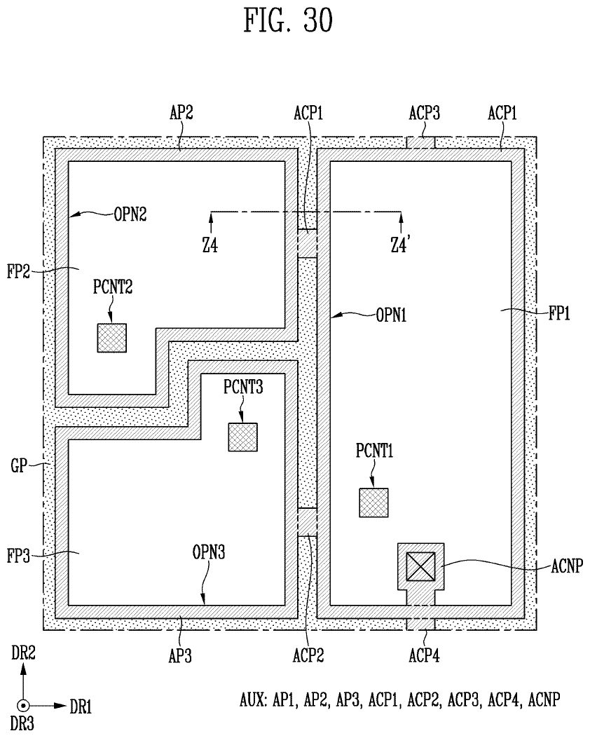

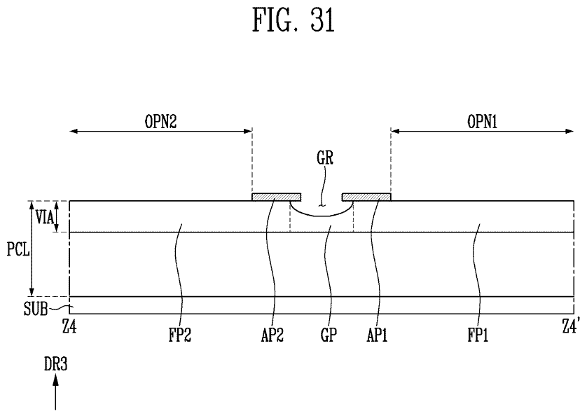

Referring to FIG. 30 and FIG. 31, the second photoresist pattern PR2 may be removed. Accordingly, the auxiliary electrode AUX described with reference to FIG. 9 and FIG. 10 may be formed.

In this step, baking the auxiliary electrode AUX may be performed. By baking, the amorphous transparent conductive oxide included in the auxiliary electrode AUX may be changed into a polycrystalline (or crystalline) transparent conductive oxide. Accordingly, the auxiliary electrode AUX may not be removed even if it is exposed to an etchant in a wet-etching process, and may maintain the shape formed in this step in subsequent steps.

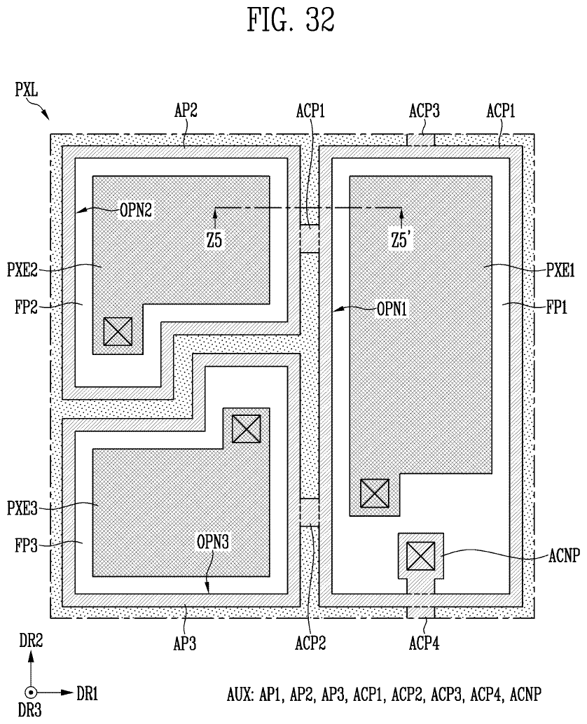

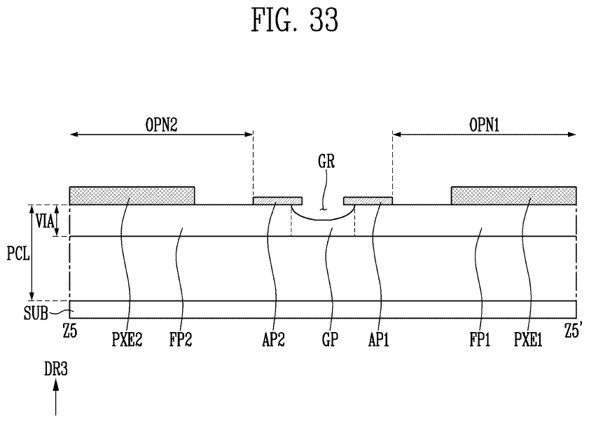

Referring to FIG. 32 and FIG. 33, first to third pixel electrodes PXE1, PXE2, and PXE3 may be formed.

The first to third pixel electrodes PXE1, PXE2, and PXE3 may be described in the same way as described with reference to FIGS. 9 to 17. The first to third pixel electrodes PXE1, PXE2, and PXE3 may be formed by forming the entirety of pixel electrode layers as a multi-layer structure, and then patterning the pixel electrode layers (e.g., a wet-etching process using a mask). In this case, the auxiliary electrode AUX may include transparent conductive oxide polycrystallized (or crystallized) by baking as described above, and thus, in the wet-etching process for patterning the pixel electrode layers entirely formed, the auxiliary electrode AUX may not be substantially removed and may maintain shape.

In the present disclosure, the first to third pixel electrodes PXE1, PXE2, and PXE3 may be formed after the formation of the auxiliary electrode AUX is completed. Accordingly, the first to third pixel electrodes PXE1, PXE2, and PXE3 may not be affected by the wet-etching processes for forming the auxiliary electrode AUX, and thus the reliability of the first to third pixel electrodes PXE1, PXE2, and PXE3 may be effectively improved.

In contrast, when the first to third pixel electrodes PXE1, PXE2, and PXE3 are formed and then the auxiliary electrode AUX is formed, in the wet-etching processes for forming the auxiliary electrode AUX, the first to third pixel electrodes PXE1, PXE2, and PXE3 may be exposed to an etchant or the like, and thus the second pixel electrode layer CDL2 may be eluted and visually recognized as a dark spot.

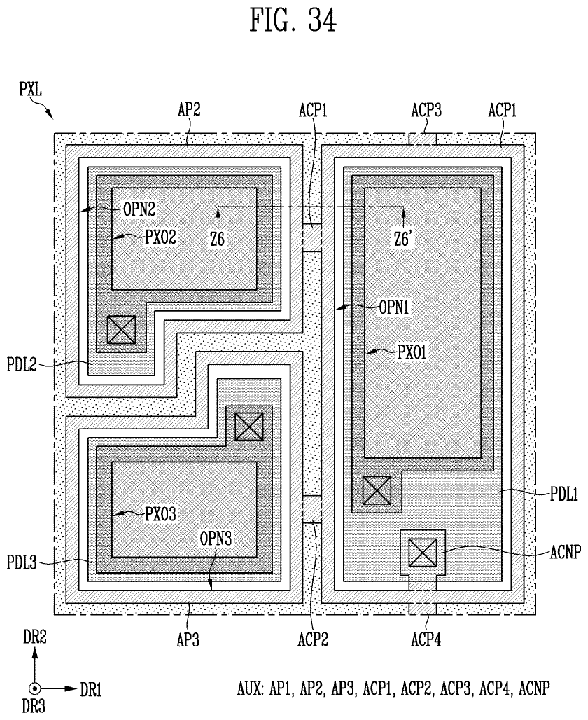

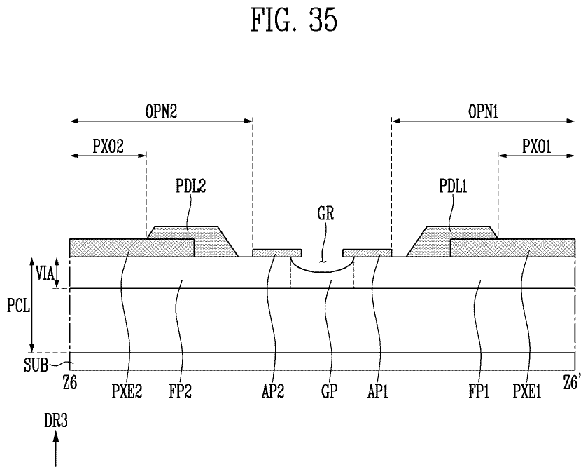

Referring to FIG. 34 and FIG. 35, first to third pixel defining layers PDL1, PDL2, and PDL3 may be formed. The first to third pixel defining layers PDL1, PDL2, and PDL3 may be described in the same way as the first to third pixel defining layers PDL1, PDL2, and PDL3 described with reference to FIG. 10.

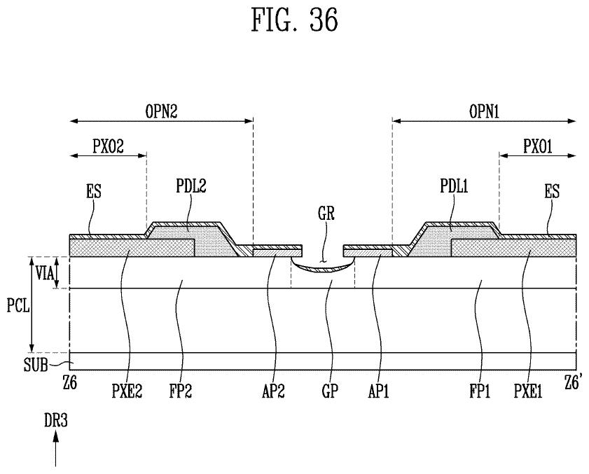

Referring to FIG. 36, a light emitting structure ES may be entirely formed. In this step, it is described in the same way as described with reference to FIGS. 9 to 16 that the light emitting structure ES may be disconnected in some areas by the groove GR and the auxiliary electrode AUX.

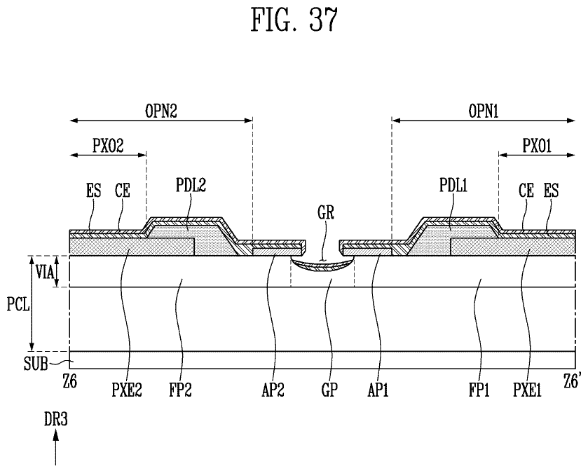

Referring to FIG. 37, a common electrode CE may be entirely formed. In this step, it is described in the same way as described with reference to FIGS. 9 to 16 that the common electrode CE may be disconnected in some areas by the groove and the auxiliary electrode AUX and may electrically contact the auxiliary electrode AUX.

A display device according to an embodiment is applicable to various types of electronic device. In an embodiment, an electronic device includes the above-described display device and may further include other modules or devices having additional functions in addition to the display device.

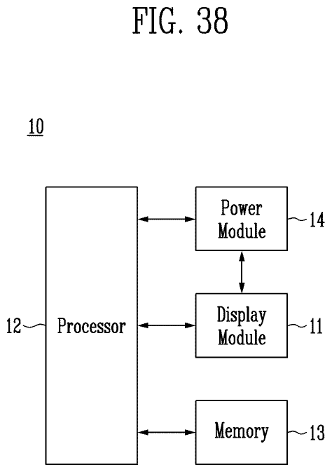

FIG. 38 is a block diagram of an electronic device according to an embodiment. Referring to FIG. 38, an electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

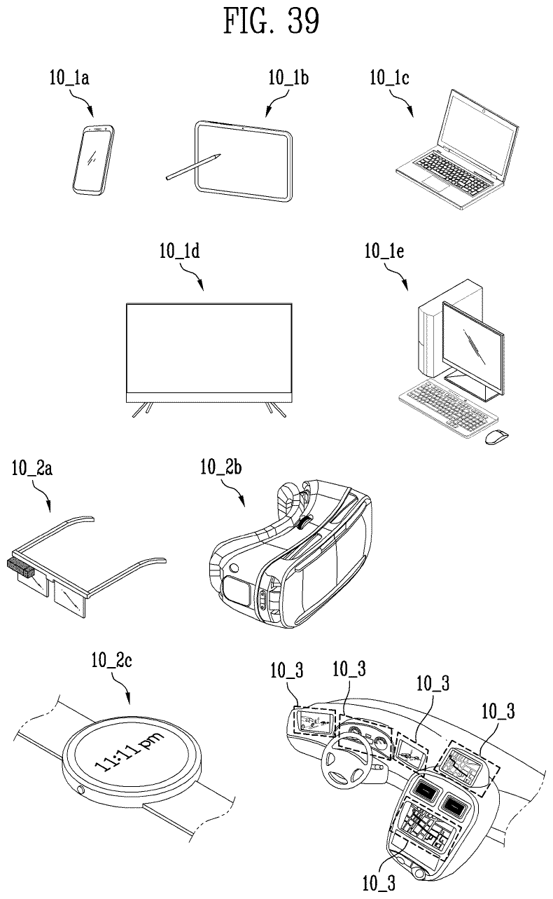

FIG. 39 shows schematic views of various embodiments of an electronic device.

Referring to FIG. 39, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

While embodiments have been described above, those skilled in the art will appreciate that various modifications, additions and substitutions are possible, without departing from the scope and spirit of the present disclosure claimed in the appended claims.

What is claimed is:

1. A display device, comprising:
a pixel circuit layer comprising a via-layer; and
an auxiliary electrode and a pixel electrode disposed on the via-layer and spaced apart from each other,
wherein the via-layer comprises: a raised portion comprising a first flat portion and a second flat portion spaced apart from the first flat portion; and a recessed portion defining a groove recessed along a periphery of the raised portion,
the auxiliary electrode comprises: a first auxiliary electrode portion defining a first opening exposing a portion of the first flat portion; and a second auxiliary electrode portion defining a second opening exposing a portion of the second flat portion,
the pixel electrode comprises: a first pixel electrode disposed on the first flat portion exposed by the first opening; and a second pixel electrode disposed on the second flat portion exposed by the second opening,
a first undercut is defined by the first auxiliary electrode portion and a portion of the recessed portion adjacent to the first flat portion, and
a second undercut is defined by the second auxiliary electrode portion and a portion of the recessed portion adjacent to the second flat portion.

2. The display device according to claim 1, wherein the auxiliary electrode comprises a polycrystalline transparent conductive oxide.

3. The display device according to claim 2, wherein the auxiliary electrode comprising a polycrystalline indium tin oxide (p-ITO).

4. The display device according to claim 2, wherein the auxiliary electrode is a single-layer structure.

5. The display device according to claim 1, wherein the pixel electrode comprises a metal.

6. The display device according to claim 5, wherein the pixel electrode is a multi-layer structure comprising: a first pixel electrode layer comprising a transparent conductive oxide; a second pixel electrode layer comprising a metal; and a third pixel electrode layer comprising a transparent conductive oxide.

7. The display device according to claim 1, further comprises:
a light emitting structure disposed on the via-layer, the auxiliary electrode, and the pixel electrode; and
a common electrode disposed on the light emitting structure.

8. The display device according to claim 7, wherein each of the light emitting structure and the common electrode is disconnected by the first undercut and the second undercut.

9. The display device according to claim 8, wherein the common electrode electrically contacts the auxiliary electrode.

10. The display device according to claim 9, wherein the common electrode electrically contacts each of a side surface of the first auxiliary electrode portion adjacent to the first undercut and a side surface of the second auxiliary electrode portion adjacent to the second undercut.

11. The display device according to claim 10, wherein the light emitting structure is disposed between the common electrode and each of an upper surface of the first auxiliary electrode portion adjacent to the side surface of the first auxiliary electrode portion and an upper surface of the second auxiliary electrode portion adjacent to the side surface of the second auxiliary electrode portion.

12. The display device according to claim 1, wherein the first auxiliary electrode portion overlaps a boundary between the first flat portion and the recessed portion in a plan view, and
the second auxiliary electrode portion overlaps a boundary between the second flat portion and the recessed portion in the plan view.

13. The display device according to claim 1, wherein the raised portion further comprises a first connection portion between the first flat portion and the second flat portion, and
the auxiliary electrode further comprises a first connection electrode portion disposed on the first connection portion and electrically connecting the first auxiliary electrode portion and the second auxiliary electrode portion to each other.

14. The display device according to claim 1, wherein the auxiliary electrode further comprises an auxiliary voltage receiving portion extending from the first auxiliary electrode portion toward the first pixel electrode, and
the auxiliary voltage receiving portion is electrically connected to an auxiliary voltage line included in the pixel circuit layer through a through-hole defined in the first flat portion.

15. The display device according to claim 1, further comprises:
a first pixel defining layer disposed on the first flat portion in the first opening and exposing at least a portion of the first pixel electrode; and
a second pixel defining layer disposed on the second flat portion in the second opening and exposing at least a portion of the second pixel electrode.

16. The display device according to claim 1, wherein the raised portion further comprises a third flat portion spaced apart from the first and the second flat portions,
the auxiliary electrode further comprises a third auxiliary electrode portion defining a third opening exposing a portion of the third flat portion,
the pixel electrode further comprises a third pixel electrode disposed on the third flat portion exposed by the third opening, and
a third undercut is defined by the third auxiliary electrode and a portion of the recessed portion adjacent to the third flat portion.

17. The display device according to claim 16, wherein the common electrode electrically contacts a side surface of the third auxiliary electrode portion adjacent to the third undercut.

18. The display device according to claim 16, wherein the third auxiliary electrode portion overlaps a boundary between the third flat portion and the recessed portion in a plan view.

19. The display device according to claim 16, wherein the raised portion further comprises a second connection portion between the first flat portion and the third flat portion, and
the auxiliary electrode further comprises a second connection electrode portion disposed on the second connection portion and electrically connecting the first auxiliary electrode portion and the third auxiliary electrode portion to each other.

20. An electronic device, comprising:
a display device, which displays an image; and
a processor, which provides an image data signal to the display device,
wherein the display device comprises: a pixel circuit layer comprising a via-layer; and an auxiliary electrode and a pixel electrode disposed on the via-layer and spaced apart from each other,
the via-layer comprises: a raised portion comprising a first flat portion and a second flat portion spaced apart from the first flat portion; and a recessed portion defining a groove recessed along a periphery of the raised portion,
the auxiliary electrode comprises: a first auxiliary electrode portion defining a first opening exposing a portion of the first flat portion; and a second auxiliary electrode portion defining a second opening exposing a portion of the second flat portion,
the pixel electrode comprises: a first pixel electrode disposed on the first flat portion exposed by the first opening; and a second pixel electrode disposed on the second flat portion exposed by the second opening,
a first undercut is defined by the first auxiliary electrode portion and a portion of the recessed portion adjacent to the first flat portion, and
a second undercut is defined by the second auxiliary electrode portion and a portion of the recessed portion adjacent to the second flat portion.
